(19) United States
(12) Patent Application Publication
(10) Pub. No.: US 2022/0242992 A1
(43) Pub. Date: Aug. 4, 2022

(54) LIGHT PATTERNING OF INORGANIC MATERIALS

(71) Applicant: CORNELL UNIVERSITY, Ithaca, NY (US)

(72) Inventors: Jen-Yu Huang, Ithaca, NY (US); Tobias Hanrath, Ithaca, NY (US); Han-Yuan Liu, Ithaca, NY (US)

(21) Appl. No.: 17/621,910

(22) PCT Filed: Jun. 24, 2020
(86) PCT No.: PCT/US2020/039467

§ 371 Date: Dec. 22, 2021

Related U.S. Application Data
(60) Provisional application No. 62/865,722, filed on Jun. 24, 2019.

(51) Int. Cl. C08F 292/00; C09D 133/10; B33Y 10/00; B33Y 70/10; B29C 64/165

(52) U.S. Cl. CPC C08F 292/00; C09D 133/10; B33Y 80/00; B33Y 70/10; B29C 64/165; B33Y 10/00

(57) ABSTRACT

Compositions including a plurality of reactive components. The reactive components each include an inorganic core with one or more photoresponsive ligand(s) covalently bonded to a surface of the inorganic core. A composition may also include a photoinitiator. Methods of making an article of manufacture includes photochemically reacting at least a portion of one or more layer(s) formed from one or more composition(s). The photochemical reaction may be carried using a laser as a source of electromagnetic radiation. An article of manufacture, which may be a three-dimensional article of manufacture, may be or is a part of a microfluidic device, HPLC column, fluidic channel, point of care device, or diagnostics device.

### CROSS REFERENCE TO RELATED APPLICATIONS

This application claims priority to U.S. Provisional Application No. 62/865,722, filed on Jun. 24, 2019, the disclosure of which is hereby incorporated by reference.

### STATEMENT REGARDING FEDERALLY SPONSORED RESEARCH OR DEVELOPMENT

This invention was made with government support under grant number 1635433 awarded by the National Science Foundation. The government has certain rights in the invention.

### BACKGROUND OF THE DISCLOSURE

Nature is replete with hierarchically structures designed with macroscopic shape and nano-scale details. Analogous hierarchical assembly strategies in synthetic systems (e.g., metal-organic frameworks, MOFs) have intrigued scientist and engineers for years. However, although the diversity of the library of available of nanostructured building blocks continues to grow, our ability to fabricate porous 3D structures from these building blocks is still in its infancy compared to the complexity commonly found in natural systems.

Photochemistry has been broadly applied to the polymer synthesis, functionalization and advanced materials production over decades. The unique advantages of precise control over reaction dynamic and geometry differentiate light-triggered reaction from indiscriminate reactions activated by thermal, chemical or electrochemical ways. However, the advances are boundaried by the fast chain propagation in forming macromolecules, causing commonly lack of features at smaller length scale. Although controlled/living radical polymerization (CRP) has been proposed to demonstrate finer structures such as macroporous polymeric monoliths, it is still difficult to achieve smaller pore size down to mesopore scale.

Natural systems are formed from a beautiful “bottom-up” strategy spanning multiple length scales from amino acids, protein chains, cells, tissue, to organs. Among the various non-biological bottom-up fabrication methods, additive manufacturing, also well known as 3D printing, has emerged as an attractive option to fabricate sophisticated 3D geometries in macroscopic scales. Digital light processing (DLP) 3D printing, a photoresin-based additive manufacturing technique, has come into focus by virtue of the rapid speed (50 cm/hr), micrometer resolution and low-cost desktop level system, increasing the accessibility at large. The general workflow to create 3D objects involves digitally slicing the desired 3D architecture into a series of images, which are then exposed as a sequence of UV patterns to define the cross section for each additive layer.

Recent developments in the synthesis of colloidal nanostructures with precisely programmable size, shape, and composition have been demonstrated as an exciting new opportunity space for complex architectures. Initial attempts to leverage advances in the synthesis of such colloidal nanostructures typically relied on blending nanoparticles in the resin. However, in the case of nanoparticle/polymer blends, the interactions between the nanoparticle and the surrounding are impaired, which significantly limits the functionality of the printed material.

Microporous materials possess important potential technological implications spanning storage, separation, catalysis, etc. However, the absence of monolithic forms significantly limits their mass transportation and thus practical applications. In general, separations using microporous materials are carried out using powdered materials in a low-throughput manner, leading either to a throughput-selectivity trade-off or high backpressures.

The current state-of-the-art in fabricating mesoporous materials present processing strategies for micro- and mesoporous materials aim at bottom-up approaches such as, direct deposition, gelation and structural templating. Nonetheless, the structural fidelity attainable via these techniques is limited by difficulties associated with spatially localizing the reaction or removing the templates; these limitations impede the construction of complicated higher-order superstructures. Still, the best shape controlled technique nowadays is limited to two dimensional films around several centimeters. Bridging the gap form fabricating nanoscale porous materials in 2D to 3D macroscopic architectures present a challenge.

The ability to fabricate microporous materials into structures analogous to natural hierarchically design is still in its infancy. Recent work has demonstrated fabrication of hierarchical nanoporous materials by combining nanoparticles' assemblies with light-initiated 3D printing. However, this strategy has so far been rarely used for the formation of microporous materials, as the formation of sub-nm features from nanoparticles' assemblies has not been realized.

Constructing porous architectures from macroscale to nanoscale like nature has challenges that originate from the fragile nature of pores being extremely difficult to process. The obstacle in particular appears for the cases with confined requirements, such as, for example, micron-size channels.

For instance, scaling bench work experiments down to a device, widely known as “lab on a chip,” has been proposed and applied in making novel biomedical devices. Although porous materials are important for purification or scaffold in the normal-sized lab, it is still hard to pack them into microfluidic system due to the limitation of processing. Two main types of approaches are typically adopted. One is to design special geometry trap in the devices then further transport porous materials inside; the other is directly synthesizing porous materials like porous photopolymer or silica beads into shaped devices. However, either type of material falls short of meeting new demands to fabricate more complicated devices. For the inorganic beads, although the materials possess high surface area, the requirement of high temperature (>100° C.) and difficulty to localize them limit their development. Nonetheless, the lack of control at the nanoscale leads to low surface area, normally less than 100 m²/g, and restricted number of active sites that would be used for further applications.

### SUMMARY OF THE DISCLOSURE

In an aspect, the present disclosure provides compositions. The compositions may be referred to herein as photoreactive compositions or inks. Non-limiting examples of compositions are provided herein. In various examples, a composition comprises a plurality of reactive components (which may be referred to herein individually as a monomer or a photoresponsive ligand on inorganic core (PLIC)), the individual reactive components comprising an inorganic core and one or more photoreactive ligand(s). In various examples, a composition is a colloidal suspension of the reactive components. A composition may further comprise photoinitiator component(s), crosslinker(s), oligomer(s), solvent(s), or a combination thereof.

In an aspect, the present disclosure provides methods of making articles of manufacture. A method may be an additive manufacturing method. An article of manufacture of the present disclosure, which may be a three-dimensional (3D) article of manufacture or 3D printed article of manufacture, may be made by a method of the present disclosure. A method may provide control over the porosity and/or shape of an article of manufacture, which may be a printed article of manufacture, as formed (e.g., in the absence of any post-formation (e.g., post-printing) process(es)). A method may provide desirable control over the formation process (e.g., printing process). A method may provide one or more or all of control of macroscopic shape of the article of manufacture (e.g., provide shapes, such as, for example, stars, cylinders, and the like, which may be in devices, such as, for example, microfluidic devices, artificial leaves, or the like), a combination of porosity (e.g., hierarchical porosity), or the like. A method may provide a mesoporous material.

In an aspect, the present disclosure provides articles of manufacture. An article of manufacture may be a 3D article of manufacture. An article of manufacture may be a printed article of manufacture (e.g., a 3D printed article of manufacture). An article of manufacture comprise (or be a mesoporous material). A method may be an additive manufacturing method. An article of manufacture of the present disclosure may be made by a method of the present disclosure and/or using a composition of the present disclosure. An article of manufacture may be in the form of a monolithic structure, a free-standing film, a film disposed on at least a portion of or all of a substrate, or a structure anchored in a confined environment (e.g. of a microfluidic device) such as, for example, a tube or channel or the like, or the like. An article of manufacture may comprise a network of polymerized reactive components.

In an aspect, the present disclosure provides uses of articles of manufacture of the present disclosure. The articles of manufacture can be used in various applications. In an example, the article of manufacture is a separation and/or filtration material (e.g., a separation and/or filtration monolithic material, film, and the like). A fluidic or microfluidic device may comprises such a material. A fluidic or microfluidic device may have desirable structure and/or functionality.

### BRIEF DESCRIPTION OF THE FIGURES

For a fuller understanding of the nature and objects of the disclosure, reference should be made to the following detailed description taken in conjunction with the accompanying figures.

FIG. 1 shows a three-dimensional printing PLIC assembly. (A) Schematic representation of multi-level control in the printing process. PLIC materials are used as the building units and structured by series of 2D UV images in the 3D printer. (B) The unit cell of zirconia inorganic nanocrystal with methacrylic acid surface ligands. (C) Formation of pores via connecting the building units. (D) An example of printed structure showing shape control for each layer. (E) Centimeter scale resulting parts with layer by layer stacking.

FIG. 2 shows hierarchical porous structures crossing seven order magnitude in length scale. (A) Computer-aided design and printed Cornell logo. (B and C) Optical images of free-standing 3D objects. (D) Lower magnification SEM images showing solid-like texture (E and F) Higher magnification to show pores of the same sample as in (D). (G and H) STEM and TEM images showing connection of building units to form highly porous property.

FIG. 3 shows print speed-controlled pore distribution. (A) Nitrogen sorption isotherms at 77 K with samples prepared in print speed at 0.9, 2.3 to 6 mm/hr. Slower print speed shows higher BET surface area. (B) Pore distribution with different print speed. The slower the print speed the smaller the pore domination. (C) Effect of drying methods by comparing supercritical drying and freeze-drying. (D to F) SEM images of different pore size domination controlling by print speed and drying method.

FIG. 4 shows complex devices like artificial leaf can be fabricated with 3D printing PLIC. (A) Photographic image of leaf. (B) Photographic image of artificial leaf. (C) 3D illustration of leaf structure from cross-sectional view. (D) SEM image of channels mimicking veins. (E) SEM image of small pores like stomata on the back surface (F) CO₂ capturing capacity of 3D printed artificial leaf. The figure shows modified sample with amine group and unmodified printed sample.

FIG. 5 shows x-ray scattering structure analysis. PXRD of Zr₆O₄(OH)₄-MAA PLIC before and after printing.

FIG. 6 shows additional HRTEM analysis. STEM of 3D printed Zr₆O₄(OH)₄-MAA. The building units are conserved after the reaction and form highly porous materials. The dot shows the scale of 2 nm as the comparison size with the building units.

FIG. 7 shows PLIC fusion mechanism/mechanisms for PLIC ink. The figure illustrates two possible mechanism by which PLIC ink is patterned during the processing. Mechanism I is a normal route to initiate and propagate the polymerization for photopolymer used in the 3D printer. Mechanism II is a proposed route for nanoparticle-based photoresist used in lithography; the second mechanism involves photoinitiated detachment of surface-bound ligands which change the solubility of nanoparticles. In fact, the PLIC idea combine both the photoinitiator from mechanism I and similar nanoparticles from mechanism II.

FIG. 8 shows FTIR analysis of Zr₆O₄(OH)₄-MAA before and after printing.

FIG. 9 shows photo-rheometer data for Zr₆O₄(OH)₄-MAA ink.

FIG. 10 shows nitrogen sorption isotherm for Zr₆O₄(OH)₄-MAA building units.

FIG. 11 shows PLIC resin solubility and a solvent comparison for ink formation.

FIG. 12 shows the effect of solvent chosen and processing conditions. Shrinkage of the printed samples with direct drying make cracks in (A). In addition, even the building units disperse well in the solvent like benzene, the printed samples exhibit more defects than using PGMEA as shown in (B) with supercritical drying and (C) with freeze drying. (D, E and F) demonstrates the surface area and pore-size distribution of (C).

FIG. 13 shows BET consistency of different print speed.

FIG. 14 shows BET consistency of different drying methods.

FIG. 15 shows TGA for thermal stability.

FIG. 16 shows CAD model of artificial leaf.

FIG. 17 shows (a) an illustration of spatially controlled polymerization by maskless UV light projector. (b) Workflow of regular photopolymerization starting from oligomer or monomer. The long polymer chains are formed and nanoparticles are treated as non-reactive additives. (c) Workflow of PLIC chemistry starting from nanoparticle building units. The photoresponsive monomers are used as molecule level connector in the form of ligands. The functions of nanoparticle are conserved, leading to better control in smaller length scale.

FIG. 18 shows (a) a schematic view of the zirconium methacrylate oxocluster, Zr₆O₄(OH)₄(OOCC(CH₃)═CH₂)₁₂. (b) Characterization of synthesized building units by FTIR (c) PXRD of building units before and after reaction. (d) Formation of pores by connecting building units through PLIC chemistry. (e) Nitrogen sorption isotherms with samples connected by different chemistry. (f) Pore size distribution of sample connected by PLIC chemistry.

FIG. 19 shows (a) a schematic representation of multi-level control enabled by PLIC chemistry. The porous microstructures can be fabricated in microfluidic devices by using Zr-MAA PLIC as the building units. (b) Illustration of biotin-functionalized surface for avidin detection or purification.

FIG. 20 shows (a) adsorption kinetics of streptavidin, BSA, IgG with non-functionalization material. (b) Adsorption/capture kinetics of streptavidin, BSA, IgG with biotin functionalization material. (c) Adsorption/Capture capacity of non-functionalization and biotin-functionalization material. (d) Multifunctional surfaces can be generated by chemistry like click and conjugation with the C═C on the surface of pores.

FIG. 21 shows mesoporous materials be printed inside microchannel with Zr-MAA PLIC as (a) an array of circles (b) stars. (c) Brightfield image of biotin functionalized mesoporous material before incubation of streptavidin-Alexa Fluor 488. (d) Fluorescence image of biotin functionalized mesoporous material before incubation of streptavidin-Alexa Fluor 488. (e) Brightfield image of biotin functionalized mesoporous material after incubation of streptavidin-Alexa Fluor 488. (f) Fluorescence image of biotin functionalized mesoporous material after incubation of streptavidin-Alexa Fluor 488. The scale bars are 100 μm.

FIG. 22 shows ¹H NMR (500 MHz, chloroform-d) of Zr₆O₄(OH)₄(MAA)₁₂ building units. The spectra matches the reported result supporting successfully synthesis of zirconium methacrylate oxocluster. Signals at 6.12 and 5.5 ppm correspond to the two hydrogen on methacrylate. Signals at 3.65 and 4.1 are related to the Zr—OH. Signals around 1.86 and 0.95 are CH₃ in methacrylate. The peak at 11.3 is undetectable suggesting the binding of methacrylic acid ligand onto the core.

FIG. 23 shows (a) precursors for common photopolymerization. (b) Precursors for PLIC chemistry. (c) Precursors for CLICK chemistry. SEM images of reacted samples by (d) photopolymerization (e) PLIC and (f) thiol-ene click.

FIG. 24 shows (a) the signals at 491 cm⁻¹ (Zn—O—C), 1412 cm⁻¹ (C—O) and 1551 cm⁻¹ (C═O) show the coordination bond between zinc and methacrylate group (COO—Zn). The peaks at 1640 cm⁻¹ (C═C) and stretching at 2870-2950 cm⁻¹ (C—H) indicate the existence of methacrylate group. (b) The dynamic light scattering supports the ZnO-MAA building units being size of 3-5 nm. The measurements were recorded for three times,

FIG. 25 shows Photo-rheometer results of (a) ZnO-MAA PLIC and (b) Zr-MAA PLIC. The gel point of ZnO-MAA and Zr-MAA occur at 5 and 21 s for curing 300 μm with the dosage of 17 mW/cm². The ZnO-MAA ink shows 4 times faster speed compared with Zr-MAA.

FIG. 26 shows PLIC inks in microfluidic devices.

FIG. 27 shows gas adsorption measurements and multi-scale pore size analysis. (a) Argon sorption isotherms with samples prepared in high and low concentration of building units. (b) Pore size distributions. (c) Proposed hierarchy of multi-scale porosities.

FIG. 28 shows angstrom precise separations with hierarchical design. (a) Device setups for the carcinogen removal in recent recalled drugs: syringe filled with superstructures (zoomed in on right). (b) Throughput comparison of hierarchical design and full pack design columns. Removal efficiency of (c) columns prepared with different concentration of Zr-MAA and (d) different initial concentration of NDMA contaminates.

FIG. 29 shows studies of yields. (a) Yield of drug API and carcinogen impurity. b, The carcinogen concentration after a given number of separation cycles.

FIG. 30 shows characterization of Zr-MAA building units by (a) PXRD, (b) FTIR and (c) ¹H NMR (500 MHz, chloroform-d).

FIG. 31 shows (a) models of two Zr-MAA clusters. (b) Possible arrangement of building blocks into tetrahedral, cubic, or octahedral units and (c) random formation of polyhedral subunits.

FIG. 32 shows (a) SEM image showing grains and tertiary mesopores made from phase separation. (b) TEM image showing grains in detail and spacing between them.

FIG. 33 shows (a) CO₂ sorption isotherms at 298K and (b) toluene sorption isotherms at 308K of samples in FIG. 27a. (c) Rates of toluene adsorption on superstructures with different pore size distributions.

FIG. 34 shows (a) a device prepared with molding method. (b) Schematic explanation of the setup.

FIG. 35 shows UV-vis data of (a) different concentrations of NDMA before and after separation. (b) Devices before and after wash. (c-d) The linear consistency of Irbesartan and NDMA's concentration.

FIG. 36 shows NMR of Irbesartan and NDMA before and after separation (full pack column).

FIG. 37 shows consistency of NDMA concentration measurements (a) without and (b) with internal standard.

FIG. 38 shows a schematic diagram of laminar flow in a tubular channel with porous wall.

FIG. 39 shows a plot of particle trajectories profiles with (a) length of column, (b) radius of the channel and (c) flow rate. The y-axis numbers in (a) mean the minimum inlet position of a particle to touch the wall before leaving the column. Therefore, for column length=0.25, only 10% of particles touch the wall. For column length=1, 70% of particles touch the wall.

FIG. 40 shows a schematic of a composition of the present disclosure.

### DETAILED DESCRIPTION OF THE DISCLOSURE

Although claimed subject matter will be described in terms of certain examples, other examples, including examples that do not provide all of the benefits and features set forth herein, are also within the scope of this disclosure. Various structural, logical, and process step changes may be made without departing from the scope of the disclosure.

Ranges of values are disclosed herein. The ranges set out a lower limit value and an upper limit value. Unless otherwise stated, the ranges include all values to the magnitude of the smallest value (either lower limit value or upper limit value) and ranges between the values of the stated range.

As used herein, unless otherwise stated, the term “group” refers to a chemical entity that is monovalent (i.e., has one terminus that can be covalently bonded to other chemical species), divalent, or polyvalent (i.e., has two or more termini that can be covalently bonded to other chemical species). The term “group” also includes radicals (e.g., monovalent and multivalent, such as, for example, divalent, trivalent, and the like, radicals). Illustrative examples of groups include:

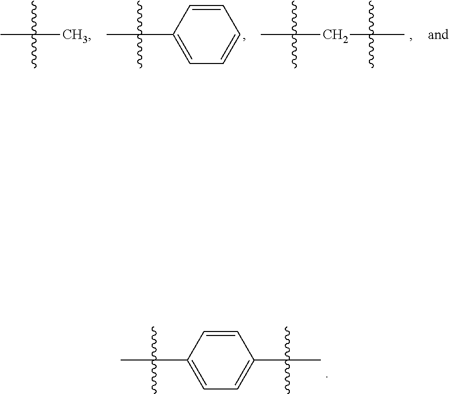

The present disclosure provides compositions, methods of making the compositions and methods of using the compositions. The present disclosure also provides articles of manufacture.

In an aspect, the present disclosure provides compositions. The compositions may be referred to herein as photoreactive compositions or inks. Non-limiting examples of compositions are provided herein.

In various examples, a composition comprises a plurality of reactive components (which may be referred to herein individually as a monomer, a precursor, or a photoresponsive ligand on inorganic core (PLIC)), the individual reactive components comprising an inorganic core and one or more photoreactive ligand(s) (e.g., 1-1000 (e.g., 1-50, 1-100, 1-500, 2-50, 2-100, 2-500, 2-1000, 3-50, 3-100, 3-500, or 3-1000 photoreactive ligand(s))), including all integer number of photoreactive ligands and ranges therebetween. In various examples, a composition is a colloidal suspension of the reactive components.

A composition can comprise various amounts of reactive components. A reactive component may provide colloidal stability to the composition. A composition may comprise various reactive components. A composition may comprise a mixture of reactive components. In various examples, the reactive components are present at 1-70 wt. % (e.g., 40-70 or 50-70 wt. %) (based on the total weight of the composition), including all 0.1 wt. % values and ranges therebetween.

A reactive component can comprise various photoreactive ligands. A photoreactive ligand may react when exposed to photons or electrons. By “react,” it is meant that a photoreactive ligand reacts to form one or more bond(s) (e.g., one or more covalent bond(s) and the like) with one or more other photoreactive ligand(s), which may be on the same and/or different reactive components. In various examples, a plurality of reactions between two photoreactive ligands on distinct reactive components constitute a polymerization reaction. A reactive component may comprise a mixture of photoreactive ligands. A photoreactive ligand may comprise one or more chelating group(s) and one or more photoreactive group(s). A chelating group can form one or more chemical bond(s) with an inorganic core. Non-limiting examples of chelating groups are described herein.

The photoreactive ligand(s) is/are bound to the inorganic core by one or more chemical bond(s). In various examples, a photoreactive ligand is/are bound to the inorganic core by one or more covalent bond(s), one or more coordinate covalent bond(s), one or more ionic bond(s), hydrogen bond(s), or the like, or a combination thereof.

A reactive component can comprise various inorganic cores. The inorganic cores, which may be nanocrystals, may exhibit one or more or all of the following properties: desirable optical properties, desirable electronic properties, desirable magnetic properties, or the like. Non-limiting examples of inorganic cores are described herein.

A photoreactive ligand may be functionalized with one or more functional group(s). In various examples, a photoreactive group is functionalized by reacting one or more of the polymerizable group(s) of one or more of the polymerizable ligands(s). In various examples, one or more photoreactive ligand(s) is functionalized with a functional group, such as, for example, an amino acid group (such as, for example, cysteine group), a glutathione group, a biotin group, a nitrilotriacetic acid (NTA) group, a iminodiacetic acid (IDA) group, a polyadenylic acid (poly (A)) group, a nucleotide group, a phospho-amino acid group, boronic acid groups, or the like, or a combination thereof. Such photoreactive ligands may be referred to herein as functionalized photoreactive ligands. In various examples, a composition further comprises one or more functionalized photoreactive ligand(s).

It is desirable that a functional group can perform various known examples of protein affinity binding and purification. As non-limiting illustrative examples, a Glutathione S-transferase (GST) tagged protein can specifically bind to glutathione; streptavidin or avidin can bind to biotin; polyhistidine (His) tagged proteins can specifically bind to nickel NTA or nickel IDA; poly(A)-binding proteins can specifically bind to the polyadenylic acid; kinases, GTPases, chaperones, motor proteins, and the like can specifically bind to nucleotides; phospho-amino acid binding proteins can specifically bind to phosphor-amino acids; and cis-diol groups within the oligosaccharide chains of glycoproteins can bind to boronic acids. In an example, the photoreactive ligand comprises one or more group(s) that can react in a functionalizing reaction and the photoreactive ligand is functionalized using one or more thio-ene reaction(s), click reaction(s), NHS amine reaction(s), or the like. In an example, the photoreactive ligand is functionalized with an amino acid group (such as for example, cysteine group and the like), a protein or peptide group (such as, for example, a streptavidin group, an avidin group, and the like), a biomolecule group (such as, for example, a vitamin group (e.g., biotin group and the like), or the like, or a combination thereof.

A composition may comprise various photoinitiator component(s). A composition may comprise a mixture of two or more photoinitiator components(s). A photoinitiator component may be a photoinitiator. Suitable photoinitiators are known in the art. The photoinitiator component(s) can be present at various amounts. In various examples, the photoinitiator component(s) is/are present at 1-10 wt. % (e.g., 0.1-10 wt. %, 1-15 wt. %, or 1-2 wt. %) (based on the total weight of the composition). A photoinitiator may be a DOLFIN photoinitiator.

A composition may comprise various crosslinker(s). Suitable crosslinkers are known in the art. The crosslinker(s) can be present at various amounts. In various examples, the crosslinker(s) is/are present at 0-60 wt. % (based on the total weight of the composition) (e.g. 0.1 to 60 wt. %), including all 0.1 wt. % values and ranges therebetween. The crosslinker(s) may comprise functional groups that react in a thio-ene reaction, a click reaction, or the like. A crosslinker may provide one or more or all of the following properties: stability, mechanical strength, or the like, to an article of manufacture and/or provide a composition with increased reaction rate (e.g., print speed), relative to a composition with the same composition except for the crosslinker(s), in an additive manufacturing method (e.g., a method of the present disclosure).

A composition may comprise one or more oligomer(s). Suitable oligomers are known in the art. The one or more oligomer(s) can be present at various amounts. In various examples, the oligomers(s) is/are present at 0-90 wt. % (based on the total weight of the composition) (e.g. 0.1 to 90 wt. %), including all 0.1 wt. % values and ranges therebetween. The upper limit of an oligomer's molecular weight may depend on its chemical nature and may equal the molecular weight of a segment, at which the substance starts demonstrating one or more or all of the following properties: superelastic strain, forced rubber-like elasticity, or the like, or other properties typically inherent to polymers. Polar and rod-like chain oligomers may have a greater range of potential molecular weight values (e.g., up to about 15,000 amu) than nonpolar oligomers (e.g., up to 5,000 amu). An oligomer may provide one or more all of the following properties: stability, mechanical strength, or the like, to an article of manufacture and/or provide a composition with increased reaction rate (e.g., print speed), relative to a composition with the same composition except for the oligomer(s), in an additive manufacturing method (e.g., a method of the present disclosure). In various examples, the oligomer(s) is/are chosen from polar chain oligomers, rod-like chain oligomers, nonpolar oligomers, and the like, and combinations thereof.

A composition may comprise one or more solvent(s). Suitable solvents are known in the art. The solvent(s) can be present at various amounts. In various examples, the solvent(s) makes up the remainder (by weight) of the composition.

A composition may have a desirable viscosity. In various examples, a composition is a low viscosity liquid.

In an aspect, the present disclosure provides methods of making articles of manufacture. A method may be an additive manufacturing method. An article of manufacture, which may be a three-dimensional (3D) article of manufacture or 3D printed article of manufacture, of the present disclosure may be made by a method of the present disclosure. A method may provide control over the porosity and/or shape of an article of manufacture, which may be a printed article of manufacture, as formed (e.g., in the absence of any post-formation (e.g., post-printing) process(es)). Non-limiting examples of methods of making articles of manufacture, which may use compositions of the present disclosure, are provided herein.

In various examples, a method (which may be an additive manufacturing method) of forming an article of manufacture, which may be a 3D article of manufacture, comprises: exposing a first layer or a selected portion of a first layer of a first composition (which may be a composition of the present disclosure (e.g., a composition of the present disclosure)) to electromagnetic radiation (e.g., light, which may be provided by a laser and/or may be spatially coherent) such that a plurality of the reactive components of the composition react and a first layer of a material (which may be i) a polymerized material and/or ii) separated from the unreacted reactive components (e.g., precursors) and/or iii) continuous or discontinuous)) is formed; optionally, forming a second layer of a second composition, optionally, exposing the second layer or a selected portion of the second layer of the second composition to electromagnetic radiation (e.g., light, which may be provided by a laser and/or may be spatially coherent) such that a plurality of reactive components of the second composition react and a second layer of a material (which may be i) a polymerized material and/or ii) separated from the unreacted reactive components (e.g., precursors) and/or first layer of material and/or iii) continuous or discontinuous)) is formed, and optionally, repeating the forming and exposing (e.g., the forming a layer of composition and exposing the layer or a portion thereof to electromagnetic radiation such that a plurality of reactive components react to form a layer of material as described herein) a desired number of times, where the article of manufacture (e.g., an article of manufacture comprising a plurality of layers of material) is formed.

A method may provide desirable control over the formation process (e.g., printing process). A method may provide one or more or all of control of macroscopic shape of the article of manufacture (e.g., provide shapes such as, for example, stars, cylinders, which may be in devices such as, for example, microfluidic devices, artificial leaves, and the like), a combination of porosity (e.g., hierarchical porosity), or the like.

A method may provide a mesoporous material. In various examples, a mesoporous material is fabricated with controlled pore size distribution and macroscopic shape within the flow channel of a fluidic or microfluidic device, which may be used for separation (e.g., bioseparation or other processes) or in a separation method.

A method is typically carried out at room temperature (e.g., 18 to 25° C.). A method may not require post-processing thermal annealing. This may be desirable in the manufacturing of structures and devices with a low thermal budget.

Various wavelengths of electromagnetic radiation can be used. Each individual selection of the wavelength(s) of electromagnetic radiation may be based on the particular photoinitiator(s) used.

One or more photoreactive ligand(s) may be reacted with a precursor (e.g., a suitably functionalized amino acid, glutathione, biotin, nitrilotriacetic acid (NTA), iminodiacetic acid (IDA), polyadenylic acid (poly (A)), nucleotide, phospho-amino acid, boronic acid, and the like, and combinations thereof) to form an amino acid group (such as, for example, a cysteine group), glutathione group, biotin group, nitrilotriacetic acid (NTA) group, iminodiacetic acid (IDA) group, polyadenylic acid (poly (A)) group, nucleotide group, phospho-amino acid group, boronic acid groups, or the like, or a combination thereof. In various examples, one or more of the composition(s) further comprise one or more reactive component(s) comprising one or more functionalized photoreactive ligand(s).

A photoreactive ligand comprising one or more group(s) that can react in a functionalizing reaction. The functionalizing reaction may be carried out prior to, during, or after formation of the article of manufacture. In various examples, a method comprises one or more functionalizing reaction(s) where the photoreactive ligand is functionalized using one or more thio-ene reaction(s), one or more click reaction(s), one or more NHS amine reaction(s), or the like, or a combination thereof, where the photoreactive ligand is functionalized, for example, with an amino acid group (such as for example, cysteine group, or the like), a protein or peptide group (such as, for example, a streptavidin group, an avidin group, or the like), a biomolecule group (such as, for example, a vitamin group (e.g., biotin group and the like), and the like, or a combination thereof.

In an aspect, the present disclosure provides articles of manufacture. An article of manufacture may be a three-dimensional (3D) article of manufacture. An article of manufacture may be a printed article of manufacture (e.g., a 3D printed article of manufacture). An article of manufacture comprise (or be a mesoporous material). A method may be an additive manufacturing method. An article of manufacture of the present disclosure may be made by a method of the present disclosure and/or using a composition of the present disclosure. Non-limiting examples of articles of manufacture are provided herein.

An article of manufacture may be in the form of a monolithic structure, a free-standing film, a film disposed on at least a portion of or all of a substrate, or a structure anchored in a confined environment (e.g. of a microfluidic device) such as, a tube or channel or the like, or the like. For example, the mesoporous material can be fabricated with controlled pore size distribution and macroscopic shape within the flow channel of a microfluidic device, which may be used for bio separation and other processes.

An article of manufacture may comprise a network of polymerized reactive components. In various examples, at least a portion of or all of the article of manufacture has a microporous network, a mesoporous network, a macroporous network, or a combination thereof. An article of manufacture may have a desirable distribution (e.g., relative ratio) of pore sizes (e.g., micropores, mesopores, macropores, or a combination thereof), which may be based on total pore volume of, if present, micropores and/or mesopores and/or macropores, if present. The terms microporous and/or mesoporous are as defined by IUPAC).

A 3D article of manufacture according may be porous (e.g., mesoporous, microporous, or a combination thereof), optionally, wherein at least a portion or all of the pores are interconnected (e.g., the article of manufacture comprises a network of polymerized reactive components and/or at least a portion or all of the inorganic cores are mesoporous and/or the inorganic pores are oriented such that the form a microporous network, or a combination thereof.

A 3D article of manufacture may have hierarchical porosity. In the case of a 3D article of manufacture with hierarchical porosity, the size of the pores (e.g., macropores) may generally decrease or increase along a dimension moving from a first surface of the article of manufacture to a second surface opposite the first surface. The gradient may be a linear gradient or a non-linear gradient. The size of the pores (e.g., macropores) generally decrease or increase along a dimension moving from a first surface of the article of manufacture to a second surface opposite the first surface. The gradient may be a linear gradient. The article of manufacture may comprise mesopores and/or macropores.

In an aspect, the present disclosure provides uses of articles of manufacture of the present disclosure. The articles of manufacture may be used in various applications. Non-limiting examples of uses of the articles of manufacture are provided herein.

In an example, the article of manufacture is a separation and/or filtration material (e.g., a separation and/or filtration monolithic material, film, or the like). A fluidic or microfluidic device may comprises such a material. A fluidic or microfluidic device may have desirable structure and/or functionality.

Integration of one or more mesoporous material(s) of the present disclosure (e.g., an article of manufacture of the present disclosure) into microfluidic devices is expected to expand the functionality of such devices. The wide range of porosity provided by a mesoporous material of the present disclosure (e.g., an article of manufacture of the present disclosure) enables a range of separation processes relevant to, for example, separation of biomolecules (such as, for example, proteins and small molecules) for applications such as, for example, biomedical diagnostics; or separation of chemicals for other diagnostic/analytical chemistry applications. The use of inorganic cores (e.g., metallic, metal oxide, semiconducting cores which may have other functionality(ies)) may provide one or more microfluidic channel(s) with additional functionality. As a non-limiting, illustrative example, using a semiconducting core (e.g. quantum dot) introduces optical and optoelectronic functionalities that can be utilized in diagnostic methods (e.g. using PL quenching as an in-situ biomolecule diagnostic within the pores of the material). Also, metal and metal oxide cores may provide electrically conductive mesoporous matrices that can be exploited for integration of, for example, electrophoretic functionality or additional diagnostic capability (e.g., electrical read out of signal modulated by interaction with, for example, specific antibody bound to porous material).

In various examples, an article of manufacture is used in a separation method. A method may be a biomolecule separation. A method may be based on size exclusion, affinity, charge, or the like. In various other examples, an article of manufacture is used in an analytical method, a drug delivery method, a sensing method, which may be a biosensing method, a catalytic method, which may be a biocatalytic method, or the like.

The following Statements describe various examples of the compositions, methods, and articles of manufacture of the present disclosure:

Statement 1. A composition (e.g., a photoreactive composition) (which may be referred to herein as an ink) comprising a plurality of reactive components (which may be referred to herein individually as a monomer, a precursor, or a photoresponsive ligand on inorganic core (PLIC)), the individual reactive components comprising an inorganic core, which may be mesoporous and/or microporous (e.g., as defined by IUPAC), and one or more photoreactive ligand(s) (e.g., 1-1000 photoreactive ligands (e.g., 1-50, 1-100, 1-500, 2-50, 2-100, 2-500, 2-1000, 3-50, 3-100, 3-500, or 3-1000), including all integer number of photoreactive ligands and ranges therebetween), which may react when exposed to photons or electrons and/or provide colloidal stability to the composition, where the photoreactive ligands are bound to the inorganic core by one or more chemical bond(s) (e.g., covalent bond(s), coordinate covalent bond(s), ionic bond(s), hydrogen bond(s), or the like, or a combination thereof). In an example, the composition is a colloidal suspension of the reactive components. In an example, the reactive components are present at 1-70 wt. % (e.g., 40-70 or 50-70 wt. %) (based on the total weight of the composition), including all 0.1 wt. % values and ranges therebetween. In an example, a mixture of reactive components may be used. In an example, the photoreactive ligands comprise one or more chelating group(s) and one or more photoreactive group(s). Non-limiting examples of chelating groups include thiol/thiolate groups, carboxylic acid/carboxylate groups, amine groups, silanol groups, and the like, and combinations thereof. Non-limiting examples of photoreactive groups include carbon-carbon double bonds (which may be terminal groups), acrylate groups, thiol groups, ester group, heterocyclic group, epoxy group (e.g. oxirane) and the like, and combinations thereof.
Statement 2. A composition according to Statement 1, where the inorganic core is chosen from metal cluster compounds (e.g., [Zr₆O₄(OH)₄]⁺¹², Hf₆O₄(OH)₄, RE₆O_{X}(OH)_{Y}, where X+Y=8 and RE=Rare Earth metals (e.g., Y and Lanthanide metals), ZnO, silica, copper oxide and other metal oxide complexes), metal, metal oxide, or semiconductor nanoparticles or nanoparticle complexes (e.g., nanocrystals, which may exhibit one or more or all of desirable optical properties, desirable electronic properties, desirable magnetic properties, or the like) (e.g., nanoparticles/nanoparticle complexes/nanocrystals having a size (e.g., a longest dimension) of 1 to 10 nm), and the like, and combinations thereof.
Statement 3. A composition according to any one of Statements 1 or 2, where the photoreactive ligand(s) are chosen from acrylate ligands (e.g., acrylic acid, methacrylic acid, mono-2-(methacryloyloxy)ethyl maleate, 2-carboxyethyl acrylate, 3-sulfopropyl acrylate potassium salt, [2-(acryloyloxy)ethyl]trimethylammonium chloride solution, 2-chloroethyl acrylate, 3-chloro-2-hydroxypropyl methacrylate, 2-aminoethyl methacrylate hydrochloride, ethylene glycol methacrylate phosphate, 3-(trimethoxysilyl)propyl methacrylate, silylated acrylate, analogs thereof, which may be functionalized analogs, derivatives thereof, and the like, and combinations thereof); alkene ligands, (e.g. 2-propenoic acid, pentenoic acid, hexenoic acid, 2-methyl-4-pentenoic acid, 7-octenoic acid, allicin, allin, analogs thereof, which may be functionalized analogs, derivatives thereof, and the like, and combinations thereof); and the like, and combinations thereof.
Statement 4. A composition according to any one of the preceding Statements, where the at least a portion of or all of the photoreactive ligands is/are functionalized (e.g., by reacting one or more polymerizable group(s) of one or more of the polymerizable ligand(s)). In an example, one or more photoreactive ligand(s) is functionalized with an amino acid group (such as for example, cysteine group), a glutathione group, a biotin group, a nitrilotriacetic acid (NTA) group, an iminodiacetic acid (IDA) group, a polyadenylic acid (poly (A)) group, a nucleotide group, a phospho-amino acid group, a boronic acid group, or the like, or a combination thereof. In an example, the photoreactive ligand comprises one or more group(s) that can react in a functionalizing reaction and the photoreactive ligand is functionalized using one or more thio-ene reaction(s), click reaction(s), NHS amine reaction(s), or the like. In an example, the photoreactive ligand is functionalized with an amino acid group (such as for example, cysteine group, or the like), a protein or peptide group (such as, for example, a streptavidin group, an avidin group, or the like), a biomolecule group (such as, for example, a vitamin group (e.g., biotin group and the like), or the like, or a combination thereof.
Statement 5. A composition according to any one of the preceding Statements, where the reactive components are chosen from Zr₆O₄(OH)₄(MAA)₁₂ (where MAA is methacrylic acid or metacylate), ZnO-MAA, Cu₂(MAA)₄, SiO₂-(3-(trimethoxysilyl)propyl methacrylic acid or methacrylate), analogs thereof, which may be functionalized analogs, derivatives thereof, and the like, and combinations thereof.
Statement 6. A composition according to any one of the preceding Statements, where the composition further comprises one or more photoinitiator(s), which may be a free-radical photoinitiator, cationic photoinitiator, nanoparticle based photoinitiator, photo-acid generator, or a combination thereof. In an example, the photoinitiator component(s) is/are present at 1-10 wt. % (e.g., 0.1-10 wt. %, 1-15 wt. %, or 1-2 wt. %) (based on the total weight of the composition). A photoinitiator may be a DOLFIN photoinitiator.
Statement 7. A composition according to Statement 6, where the photoinitiator(s) is/are chosen from free radical photoinitiators (e.g., diphenyl(2,4,6-trimethylboenzoyl phosphine oxide), phosphine oxide, phenyl bis(2,4,6-trimethyl benzoyl), bis [2,6-difluoro-3-(1H-pyrrol-1-yl) phenyl]titanium, anthraquinone-2-sulfonic acid, 4-benzoylbiphenyl, 4,4′-bis(diethylamino) benzophenone, 2-benzyl-2-(dimethylamino)-4′-morpholinobutyrophenone, 4,4′-bis(dimethylamino) benzophenone, 4-(dimethylamino) benzophenone, 2-Hydroxy-2-methyl-1-phenyl-propan-1-one, or combinations thereof), cationic photoinitiators (e.g. diphenyliodonium hexafluorophosphate, (4-Iodophenyl)diphenylsulfonium triflate, (4-tert-Butylphenyl)diphenylsulfonium triflate, or a combination thereof), nanoparticle based photoinitiators (e.g., quantum dots, zinc oxide nanoparticles, and combinations thereof), photo-acid generators (e.g., (4-methylthiophenyl) methyl phenyl sulfonium triflate, sodium 1,2,3,4-thiatriazole-5-thiolate, tris(diphenyliodonium), 9-hydroxy-pyrene-1,4,6-trisulfonate, and combinations thereof), and combinations thereof.
Statement 8. A composition according to any one of the preceding Statements, where the composition further comprises one or more crosslinker(s), which may comprise functional groups that react in a thio-ene reaction, a Click reaction, or the like and/or be present at 0-60 wt. % (based on the total weight of the composition) (e.g. 0.1-60 wt. %), including all 0.1 wt. % values and ranges therebetween.
Statement 9. A composition according to Statement 8, where the crosslinker(s) is/are chosen from di- to multi-thiol group (e.g. benzene dithiol, poly(ethylene glycol) dithiol, 1,3,4-thiadiazole-2,5-dithiol, biphenyl-4,4′-dithiol), di- to multi-acrylate group (e.g. poly(ethylene glycol) dicrylate, 1,3-butanediol diacrylate, 1,6-hexanediol diacrylate, bisphenol A ethoxylate diacrylate, ethylene glycol diacrylate, di(ethylene glycol) diacrylate, tri(ethyleneglycol) diacrylate, trimethylol propane triacrylate), and combinations thereof.
Statement 10. A composition according to any one of the preceding Statements, where the composition further comprises one or more oligomer(s), which may have a molecular weight from 100-5000 amu, including all 0.1 amu values and ranges therebetween, and/or may be present at 0-90 wt. % (based on the total weight of the composition). (e.g., 0.1-90 wt. %), including all 0.1 wt. % values and ranges therebetween.
Statement 11. A composition according to Statement 10, where the oligomer(s) is/are chosen from oligomers (e.g., oligomers having a molecular weight of 50-2500 g/mol) and polymers of epoxy acrylates, aliphatic urethane acrylates, aromatic urethane acrylates, ester acrylates, acrylic acrylates, and the like, and combinations thereof.
Statement 12. A composition according to any one of the preceding Statements, where the composition further comprises one or more solvent(s), which may make up the remainder (by weight) of the composition.
Statement 13. A composition according to Statement 12, where the solvent is/are chosen from organic solvents (e.g., aromatic solvents, such as, for example, benzene, toluene, xylene, and the like, aliphatic solvents, such as, for example, alkanes, cycloalkanes, and the like, polyethers or oligoethers, such as for example, propylene glycol monomethyl ether acetate, halogenated solvents (e.g., halogenated organic solvents), such as chloroform, dichloromethane and combinations thereof.
Statement 14. A method (which may be an additive manufacturing method) of forming an article of manufacture, which may be a three-dimensional (3D) article of manufacture, comprising: exposing a first layer or a selected portion of a first layer of precursor (which may be a composition of the present disclosure (e.g., a composition of any one of the preceding Statements)) to electromagnetic radiation (e.g., light, which may be provided by a laser and/or may be spatially coherent) such that a plurality of precursors react and a first layer of a material (which may be i) a polymerized material and/or ii) separated from the unreacted precursor and/or iii) continuous or discontinuous)) is formed; optionally, forming a second layer of precursor, optionally, exposing the second layer or a selected portion of the second layer of precursor to electromagnetic radiation (e.g., light, which may be provided by a laser and/or may be spatially coherent) such that a plurality of precursors in the second layer of precursor react and a second layer of a material (which may be i) a polymerized material and/or ii) separated from the unreacted precursor and/or first layer of material and/or iii) continuous or discontinuous)) is formed, and optionally, repeating the forming and exposing (e.g., the forming a layer of precursor and exposing the layer or a portion thereof to electromagnetic radiation such that a plurality of precursors react to form a layer of material as described herein) a desired number of times, where the article of manufacture (e.g., an article of manufacture comprising a plurality of layers of material) is formed. A method may include one or more process(es) typically used in traditional photolithographic processes (e.g., depositing/coating, patterning, development, etc.).
Statement 14a. A method of forming an article of manufacture comprising: exposing a first layer or a selected portion of a first layer of a first composition according to any one of Statements 1-13 to electromagnetic radiation such that a plurality of the reactive components of the composition react and a first layer of a polymerized material is formed; optionally, forming a second layer of a second composition according to any one of Statements 1-13, optionally, exposing the second layer or a selected portion of the second layer to electromagnetic radiation such that a plurality of the precursors of the second composition react and a second layer of a second polymerized material is formed, and where the article of manufacture is formed.
Statement 15. A method according to Statements 14 or 14a, where the first layer of material (e.g., a polymerized material) or all of the layers of polymerized material is/are translated relative to a surface of the precursor.
Statement 15a. A method according to Statements 14 or 14a, where the first layer of polymerized material or all of the layers of polymerized material is/are translated relative to a surface of the first composition according to any one of Statements 1-13.
Statement 16. A method according to any one of Statements 14-15a, further comprising: removing the first layer or all of the layers of material from the remaining (e.g., unreacted) precursor material that is unaffected by the energy.
Statement 16a. A method according to any one of claims 14-15a, further comprising removing the first layer of polymerized material or all of the layers of polymerized material from the remaining unreacted composition(s) that is unaffected by the electromagnetic radiation.
Statement 17. A method according to any one of Statements 14-16, further comprising repeating the forming and the exposing until the entire printed structure is completed (e.g., the entire article of manufacture is formed).
Statement 18. A method according to any one of Statements 14-17, where the forming and exposing are repeated 1-100, 1-1000, 1-10,000, 1-100,000 times, or 1-500,000 times.
Statement 19. A method according to any one of Statements 14-18, where the forming and exposing are repeated continuously.
Statement 20. A method according to any one of Statements 14-19, where the forming and the exposing are repeated in a batch mode.
Statement 21. A method according to any one of Statements 14-20, where the electromagnetic energy is infrared light, visible light, ultraviolet light, electron beam (e-beam), or x-ray light.
Statement 22. A method according to any one of Statements 14-21, where one or more or all of the exposing is carried out using electromagnetic radiation having a wavelength of visible light (400-700 nm), Ultraviolet A (315-400 nm), Ultraviolet B (280-315 nm), a portion of Ultraviolet C (190-280 nm), or electron beam.
Statement 23. A method according to any one of Statements 14-22, where one or more or all of the exposing and/or forming and exposing is/are carried out in pre-selected pattern (e.g., using a direct-write method, a lithographic method, digital light processing method, stereolithography method, and the like).
Statement 24. A method according to any one of Statements 14-23, where one or more or all the exposing and/or forming and exposing is/are carried out using a 3D printer, stereolithography, drop coating, spray coating, dip coating, inkjet printer, extrusion, electrospinning, or the like, or a combination thereof.
Statement 25. A method according to any one of Statements 14-24, where at least one or each layer of precursor and/or material has a thickness of a monolayer to 10 cm (e.g., 2 nm to 500 nm, 2 nm to 2 cm). A monolayer may a monolayer of reactive components, some of or all of which may be polymerized.
Statement 25a. A method according to any one of Statements 14-24, where at least one or each layer of the composition and/or material has a thickness of monolayer to 10 cm.
Statement 26. A method according to any one of Statements 14-25, further comprising contacting the article of manufacture with a solvent (e.g., organic solvent, such as, toluene, propylene glycol monomethyl ether acetate, dichloromethane, acid, such as acetic acid, methacrylic acid, and combinations thereof) and/or drying (e.g., vacuum drying) the article of manufacture.
Statement 27. A method according to any one of Statements 14-26, further comprising exchanging the article of manufacture with a solvent (e.g., water, alcoholic solvent, such as, IPA, methanol, ethanol, and combinations thereof) and/or freeze-drying the solvent exchanged article of manufacture (e.g., optionally freeze-drying the solvent exchanged article of manufacture).
Statement 28. A method according to any one of Statements 14-27, further comprising drying (e.g., vacuum drying) (e.g., removing any unreacted precursor, solvent, and the like) the article of manufacture in a near critical (e.g., a supercritical) gas (e.g., near/supercritical carbon dioxide, nitrogen, or the like).
Statement 29. A method according to any one of Statements 14-28, further comprising functionalizing at least a portion of or all of the article of manufacture (e.g., by reacting one or more unreacted polymerizable ligand(s).
Statement 30. A method according to any one of Statements 14-29, where the article of manufacture is in the form of (e.g., has a macroscopic shape of) a monolithic structure, a free-standing film, a film disposed on at least a portion of or all of a substrate, or a structure anchored in confined environment such as, tubes or channels (e.g., of a microfluidic device).
Statement 31. A method according to any one of Statements 14-30, where the article of manufacture is porous (e.g., microporous (e.g., having pores with a size (e.g., at least one dimension) of 0.1-2 nm), mesoporous (e.g., having pores with a size (e.g., at least one dimension) of 2-50 (e.g., 20-50 nm)), macroporous, or a combination thereof) (e.g., comprises intra-particle (inorganic core) micropores and/or mesopores) and/or inter-particle (inorganic core) macropores), where at least a portion or all of the pores may be interconnected. In an example, the article of manufacture comprises a network of polymerized reactive components. In an example, at least a portion or all of the article of manufacture has a microporous network, a mesoporous network, a macroporous network, or a combination thereof. An article of manufacture may have a desirable distribution (e.g., relative ratio) of pore sizes (e.g., micropores, mesopores, macropores, and combinations thereof), which may be based on total pore volume of, if present, micropores and/or mesopores and/or macropores.
Statement 32. A method according to any one of Statements 14-31, where the article of manufacture comprises macropores having at least one dimension (e.g., a height) as measured in a plane perpendicular to an axis of the pore) of 500 microns to 1 micron (e.g., 200 microns to 1 micron or 100 microns to 1 micron), and/or at least a portion of or all of the inorganic cores are microporous and/or mesoporous (e.g., microporous and/or mesoporous as defined by IUPAC).
Statement 33. A method according to any one of Statements 14-32, where the article of manufacture has a hierarchical porosity (e.g., including macropores, mesopores, micropores, or a combination thereof). As an illustrative example, the article of manufacture can possess micrometer scale porosity, 20 nanometer pores, 3 nanometer pores, and 6 Å pores between the inorganic core.
Statement 34. A method according to any one of Statements 14-33, where the article of manufacture has a hierarchical pore size gradient. The size of the pores (e.g., macropores) generally decrease or increase along a dimension moving from a first surface of the article of manufacture to a second surface opposite the first surface. The gradient may be a linear gradient or a non-linear gradient.
Statement 35. A method according to any one of Statements 14-34, where all of the layers are formed using the same composition and/or the same processing conditions (e.g., electromagnetic energy intensity, electromagnetic energy wavelength, total electromagnetic energy, layer thickness, pattern (if used), print speed (if used), and the like, and combinations thereof).
Statement 36. A method according to any one of Statements 14-35, where at least one, at least two, at least five, at least ten, at least 20, at least 50, the majority of, or all of the layers (or a portion thereof) are formed using a different composition and/or different processing conditions (at least one of inorganic core, photolithographic ligand, solvent, or the like, or a combination thereof and/or at least one process parameter (e.g., electromagnetic energy intensity, electromagnetic energy wavelength, total electromagnetic energy, layer thickness, pattern (if used), print speed (if used), and the like, and combinations thereof) is different for one or more or all of the layers (e.g., different for one or more or all of the individual exposing or exposing and forming).
Statement 37. A method according to any one of Statements 14-36, where the article of manufacture is not annealed (e.g., annealed post-formation).
Statement 38. A three-dimensional (3D) article of manufacture, which may be a 3D printed article of manufacture, (which may be made using a composition of the present disclosure (e.g., a composition of any one of Statements 1-13) or by a method of the present disclosure (e.g., a method of any one of Statements 14-37)).
Statement 38a. A three-dimensional (3D) article of manufacture comprising a network of crosslinked reactive components, the individual reactive components comprising an inorganic core, which may be mesoporous and/or microporous, and one or more photoreactive ligand(s), which may react when exposed to photons or electrons and/or provide colloidal stability to the composition, wherein the photoreactive ligands are bound to the inorganic core by one or more chemical bond(s), where at least a portion or all of the article of manufacture has a microporous network, a mesoporous network, a macroporous network, or a combination thereof.
Statement 39. A 3D article of manufacture, which may be a 3D printed article of manufacture, according to Statement 38 or Statement 38a, where the article of manufacture is in the form of a monolithic structure, a free-standing film, or a film disposed on at least a portion of or all of a substrate (e.g., a structure anchored in confined environment such as, tubes or channels of a fluidic or microfluidic device), any of which may be part of a fluidic or microfluidic device (e.g., an in situ separation column in a fluidic or microfluidic device).
Statement 40. A 3D article of manufacture, which may be a 3D printed article of manufacture, according to Statements 38, 38a, or 39, where the article of manufacture is porous (e.g., microporous (e.g., having pores with a size (e.g., at least one dimension) of 0.1-2 nm), mesoporous (e.g., having pores with a size (e.g., at least one dimension) of 20-50 nm), macroporous, or a combination thereof) (e.g., comprises intra-particle (inorganic core) micropores and/or mesopores) and/or inter-particle (inorganic core) macropores), where at least a portion of or all of the pores may be interconnected. In an example, the article of manufacture comprises a network of polymerized reactive components. In an example, at least a portion or all of the article of manufacture has a microporous network, a mesoporous network, a macroporous network, or a combination thereof. An article of manufacture may have a desirable distribution (e.g., relative ratio) of pore sizes (e.g., micropores, mesopores, macropores, and combinations thereof), which may be based on total pore volume of, if present, micropores and/or mesopores and/or macropores, if present.
Statement 41. A 3D article of manufacture, which may be a 3D printed article of manufacture, according to any one of Statements 38-40, where the article of manufacture comprises macropores having at least one dimension (e.g., a height) as measured in a plane perpendicular to an axis of the pore) of 500 microns to 1 micron (e.g., 200 microns to 1 micron or 100 microns to 1 micron), and/or at least a portion of or all of the inorganic cores are microporous and/or mesoporous (e.g., microporous and/or mesoporous as defined by IUPAC).
Statement 42. A 3D article of manufacture, which may be a 3D printed article of manufacture, according to any one of Statements 38-41, where the article of manufacture has a hierarchical porosity.
Statement 43. A 3D article of manufacture, which may be a 3D printed article of manufacture, according to any one of Statements 38-42, where the article of manufacture has a hierarchical pore gradient. The size of the pores (e.g., macropores) generally decrease or increase along a dimension moving from a first surface of the article of manufacture to a second surface opposite the first surface. The gradient may be a linear gradient. The article of manufacture may comprise mesopores and/or macropores. The mesopores may be mesopores as defined by IUPAC.
Statement 44. A 3D article of manufacture, which may be a 3D printed article of manufacture, according to any one of Statements 38-43, where the article of manufacture has a constant composition.
Statement 45. A 3D article of manufacture, which may be a 3D printed article of manufacture, according to any one of Statements 38-44, where at least a portion of (e.g., at least one, at least two, at least five, at least ten, at least 20, or at least 50 regions of, which may be individual layers as described herein) or the majority of the article of manufacture has a different composition.
Statement 45a. A 3D article of manufacture, where at least a portion of or the majority of the 3D article of manufacture has a different composition from the other portion(s) of the article of manufacture.
Statement 46. A 3D article of manufacture, which may be a 3D printed article of manufacture, according to any one of Statements 38-45, where the article of manufacture is not annealed.
Statement 47. A 3D article of manufacture, which may be a 3D printed article of manufacture, according to any one of Statements 38-46, where the article of manufacture is a part of a microfluidic device, HPLC column, fluidic channel, point of care device, diagnostics device, or the like.
Statement 48. A 3D article of manufacture, which may be a 3D printed article of manufacture, according to any one of Statements 38-47, where the article of manufacture exhibits one or more or all of the following properties: porosity (e.g., hierarchical porosity), one or more desirable mechanical propert(ies) (e.g., modulus), or the like.
Statement 49. Use of a three-dimensional (3D) article of manufacture, which may be a three-dimensional (3D) printed of manufacture of the present disclosure, (which may be made using a composition of the present disclosure (e.g., a composition of any one of Statements 1-13) or by a method of the present disclosure (e.g., a method of any one of Statements 14-37 or a 3D printed article of manufacture according to any one of Statements 38-48) in a separation method (e.g., a biomolecule separation), which may be based on size exclusion, affinity, charge, or the like, an analytical method, a drug delivery method, a sensing method, which may be a biosensing method, a catalytic method, which may be a biocatalytic method, or the like.

The steps of the method described in the various examples disclosed herein are sufficient to carry out the methods of the present disclosure. Thus, in an example, a method consists essentially of a combination of the steps of the methods disclosed herein. In another example, a method consists of such steps.

The following examples are presented to illustrate the present disclosure. The examples are not intended to be limiting in any matter.

### Example 1

The following example provides a description of compositions, methods, and articles of manufacture and uses thereof of the present disclosure.

In this example, three-dimensional printing of superstructures with multi-level porous networks starting from a specific photoresponsive building block defined by a zirconia core with 12 methacrylic acid ligands was demonstrated. It was demonstrated how the photoresin based on photoresponsive ligand on inorganic core enables a path towards a bottom-up route to program structure, composition and function. A 3D printed biomimetic artificial leaf with nature-comparable framework and functions such as carbon dioxide capture was demonstrated.

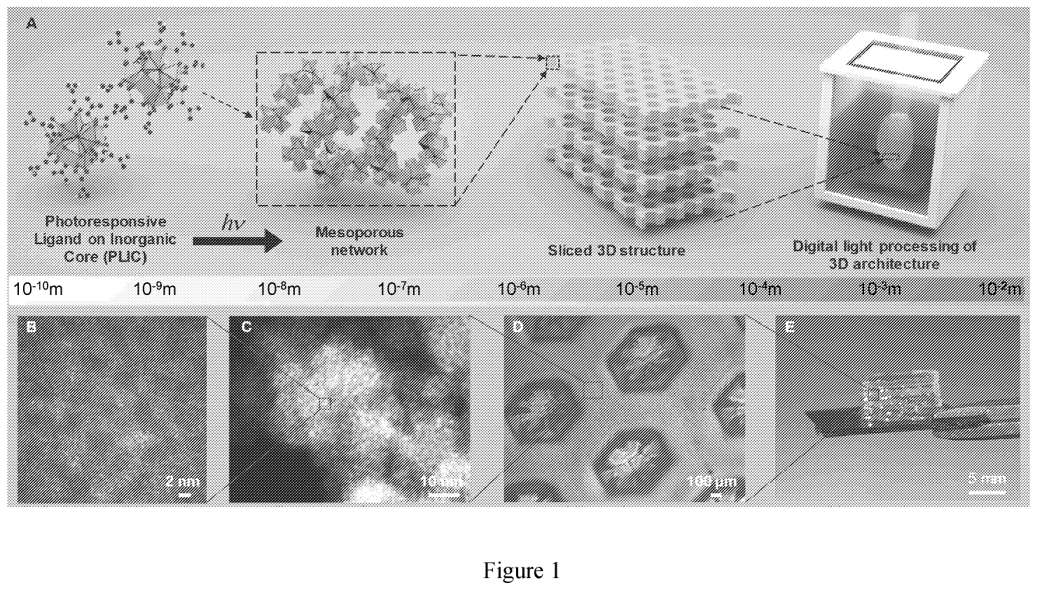

A new kind of photoresin based on photoresponsive building block defined by a zirconia core with 12 methacrylic acid ligands is introduced. FIG. 1 schematically illustrates how photoresponsive ligand on inorganic core (PLIC) chemistry can be applied in the fabrication of hierarchical porous materials. Beyond the model system of zirconia-based porous materials at the focus of this example, the PLIC resin chemistry raises broad potential to diversify material compositions that can be fabricated with DLP 3D printing.

The porous zirconia structures printed with the PLIC resin have interesting analogies to MOFs. The intra-particle and inter-particle pores will form when the PLIC building blocks are connected. The traditional solvothermal synthesis of MOFs has thus far prohibited their integration in 3D printing methods. However, the PLIC fabrication scheme used in this example uses light to spatially program where the porous materials are formed. With PLIC as 3D printing inks, predesigned structures in different length scale can be manipulated by combining the inherent porosity of connecting PLIC units at the nanoscale and the advantage of additive manufacturing at macroscopic scale that enables conventional powder-like porous materials be constructed to intricate designed architectures unattainable with conventional fabrication schemes.

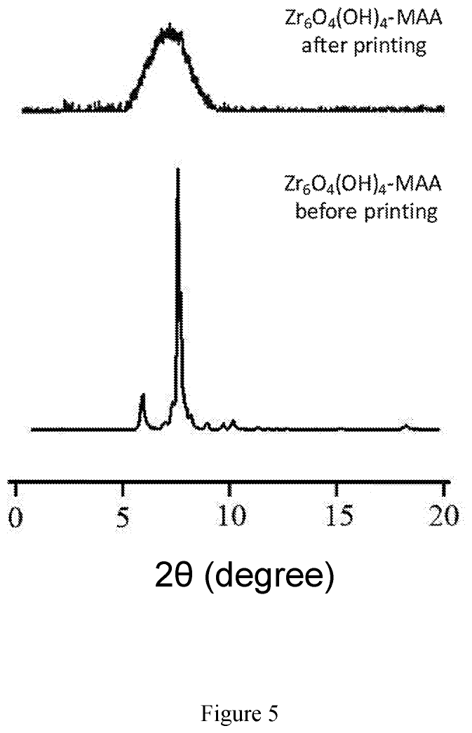

The fundamental building block of the PLIC 3D printing resin is based on Zr₆O₄(OH)₄ with 12 methacrylic acid (MAA) ligands (FIG. 1A). The structure extends from prominent zirconium-based MOF (UiO-66), possessing attractive thermal and chemical stability with ultrahigh surface area. X-ray diffraction (XRD) patterns further confirms the match between simulated and synthesized (FIG. 5). The methacrylic acid ligands serve two functions: first to provide colloidal stability and second as a molecular connector by photopolymerizing the carbon double bond. As demonstrated below, we note that additional functionalities can be obtained by exchanging the surface-bound ligands after processing. The inherent compatibility with a broad spectrum of ligand chemistries makes this approach interesting for applications separation applications that rely on programmable interactions between the fluid and the functionalized surface of the particle.

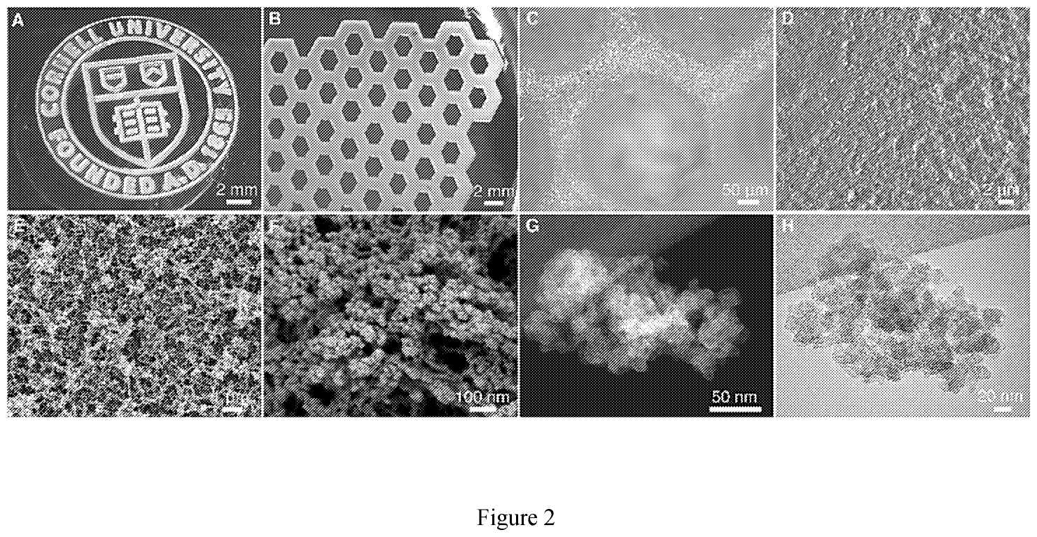

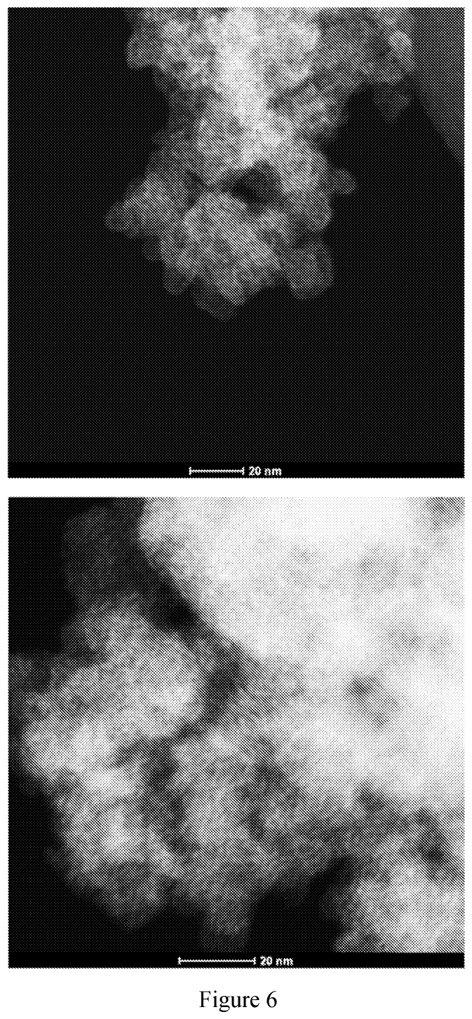

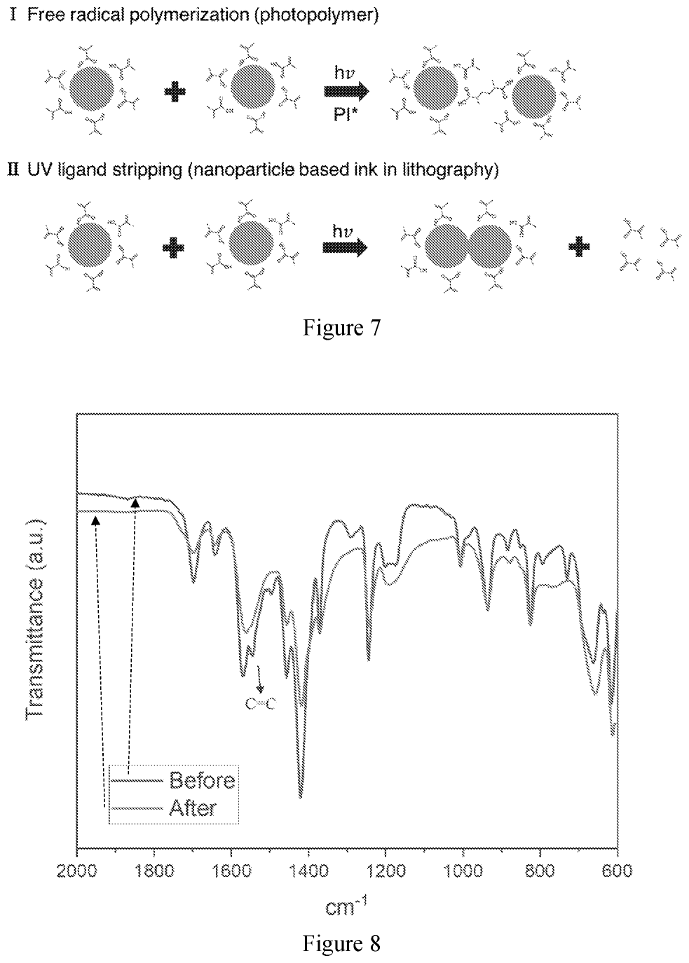

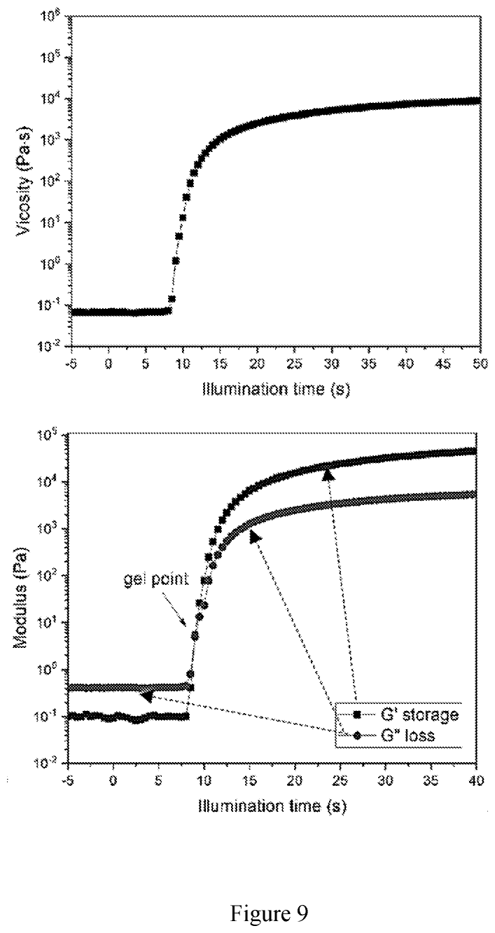

The connection between PLIC building blocks was spatially programmed by controlling the region in which free radical polymerization is photoinitiated (FIG. 1, C-E, FIGS. 6 and 7). To fabricate the superstructure (the Cornell logo as shown in FIGS. 2, A and B), the PLIC ink was formulated by dissolving Zr₆O₄(OH)₄-MAA in the proper solvent with UV free-radical photo initiator (0.2 wt %) and used in the 3D printer. Fourier-transform infrared spectroscopy (FTIR) of Zr₆O₄(OH)₄-MAA films before and after UV exposure in the 3D printer support the interpretation that the C═C bonds cross-link the Zr₆O₄(OH)₄-MAA building blocks (see decreasing C═C vibrational signature near 1600 cm⁻¹ after printing, FIG. 8). Moreover, this processing approach allows us to build the monolithic superstructure with the vertical speed of tens of millimeters per hour, which is only slightly slower than normal resin, showing both the potential to build devices and broader prospects for scalable nanofabrication (FIG. 9).

To gain deeper insights into the structure of the mesoporous films, scanning and transmission electron microscopy (SEM & TEM) was used. FIG. 2 demonstrates the breakdown of hierarchical length scales, supporting primary, secondary, and tertiary networks can be constructed by 3D printing PLIC porous materials. At lower magnification, solid like texture and different geometries shows precisely programed fabrication without clear defect over large area (FIG. 2, A to D). At higher magnification, the SEM images reveal the spongy texture with inter-particle and intra-particle pores by connecting Zr₆O₄(OH)₄-MAA building blocks (FIG. 2, E to H). The net-like porous walls (FIG. 2E) are constructed from closely packed building blocks (FIG. 2F-H) resulting in a broad range of pore size distributions which can be tailored by changing the printing conditions as shown below.

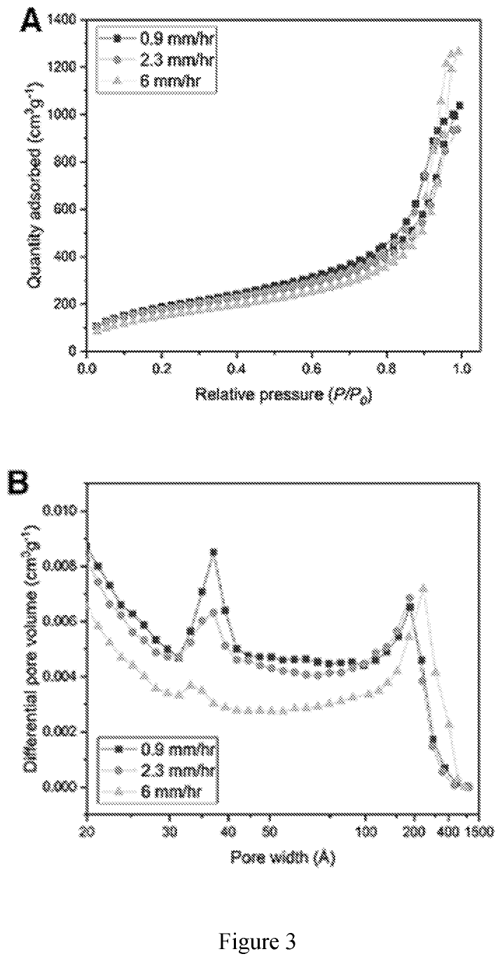

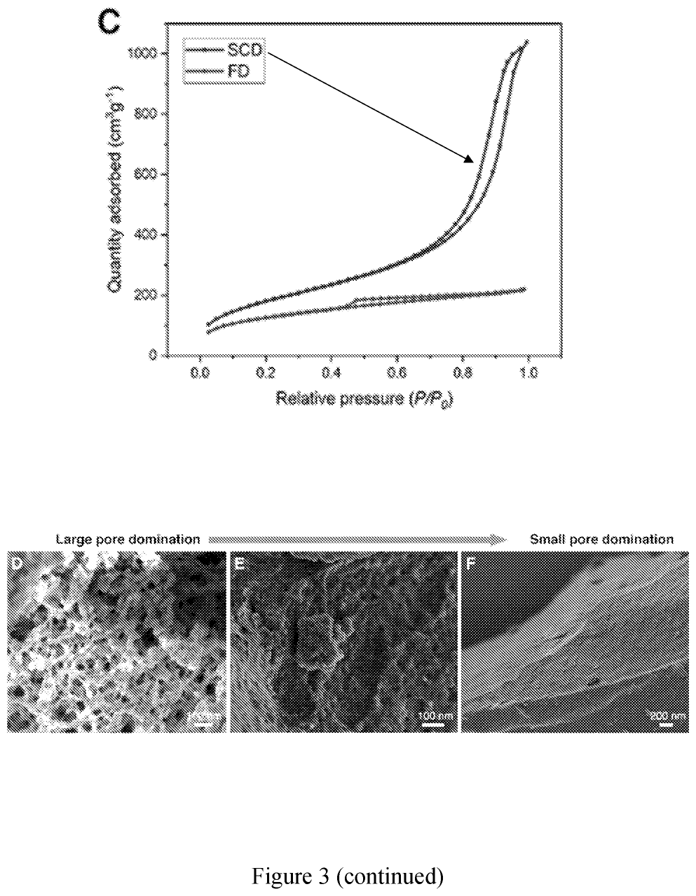

The permanent nanoscale porosity of 3D printed structures was confirmed by measuring nitrogen adsorption and desorption isotherms at 77 K. The profile shows typical type IV isotherm with hysteretic loop, indicating the feature of mesoporous materials. The printed superstructure exhibits high surface area and expected pore size distribution supported by the Brunauer-Emmett-Teller (BET) surface area with 679 m² g⁻¹ (Langmuir surface area: 1038 m² g⁻¹) and Barrett-Joyner-Halenda (BJH) theory calculation of 3.7 nm and 18 nm pore width domination (FIGS. 3, A and B), stands in good agreement with the electron microscopy results shown above.

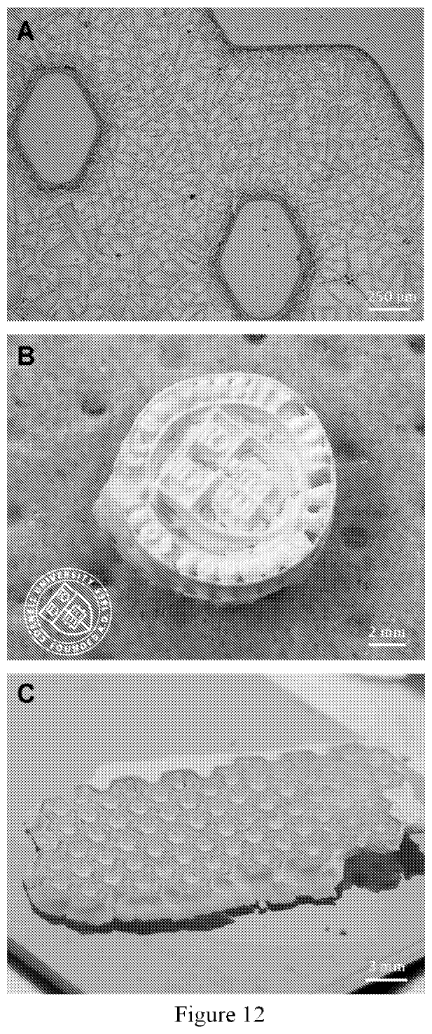

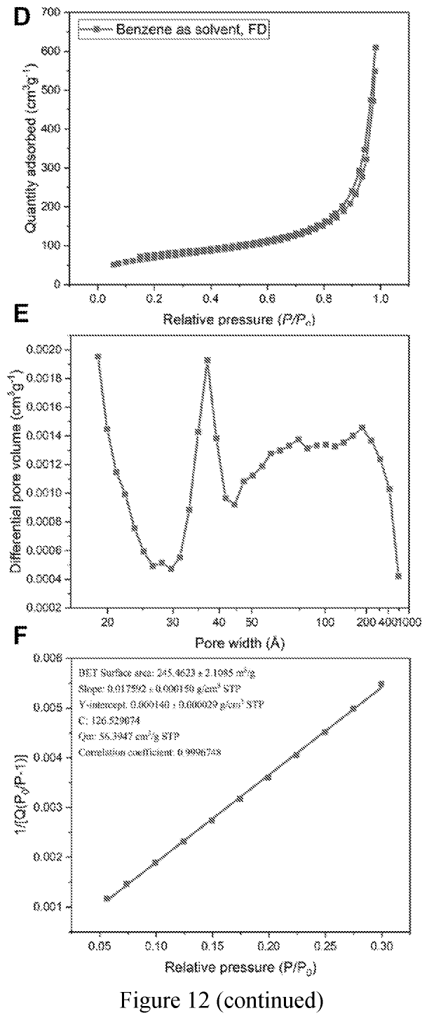

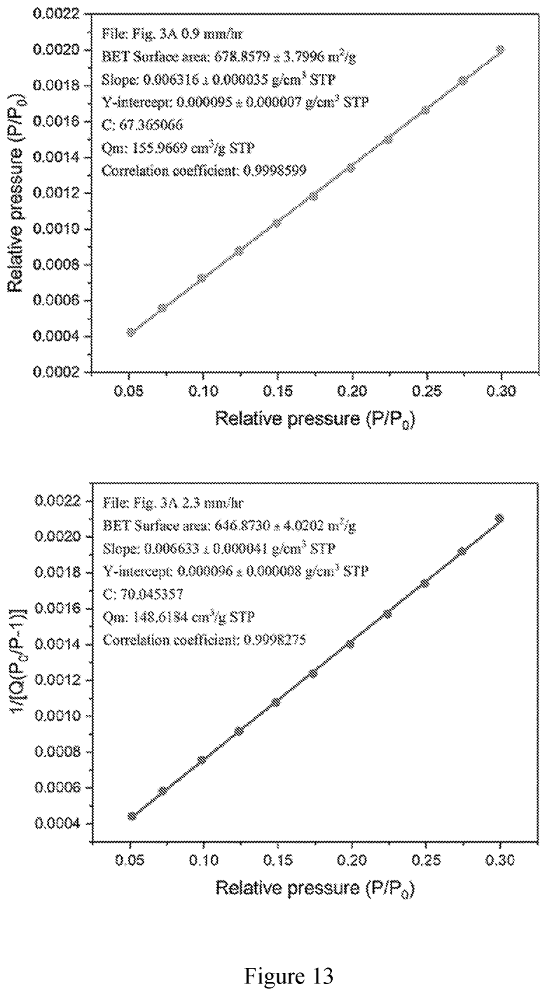

The 3D printed mesoporous structures described herein can be fabricated without the need for post-printing thermal annealing. In contrast to many of the recently reported 3D printing resins for glass, metals, and ceramic, which all require post-printing annealing, the mesoporous structures described in this example can be formed in one step, which greatly simplifies the overall processing workflow. Successful implementation of PLIC inks requires consideration of multiple interacting parameters including, viscosity, solubility of the building blocks, light transmittance and radical stability, and solvent choice. A range of aliphatic and aromatic solvents (see below) were investigated and it was found that using propylene glycol monomethyl ether acetate (PGMEA) as a solvent enables the formation of defect-free centimeter scale glass-like honeycomb structures shown in FIG. 2C. Aromatic solvents on the other hand appear to diminish the reactivity of the complexed radical, which impacts both the porosity and the macroscopic appearance of the printed structure (see below). In films processed from inks dissolved in benzene, the BET surface area decreases to 245 m² g⁻¹ and abundance of defects that turn transparent results to white powder appearance can be observed (FIG. 12).

The pore size distribution can be tuned by adjusting the 3D print speed. The trade-off between print speed and the ratio of intra- and inter-particle is demonstrated with BJH pore distribution in FIGS. 3A and B, from 0.9 mm/hr to 6 mm/hr. With higher print speed (i.e., less reaction time) the inter-particle 20 nm pores dominate and the signal for intra-particle pore is comparably negligible. By contrast, when the structures are printed at a slower speed (longer reaction time per layer), the porous structure is dominated by intra-particle 3.7 nm pores since the building blocks have more time to pack denser arrangements in each layer. The SEM images (FIG. 3, D to F) elucidate the diverse textures by tailoring the ratio of intra- and inter-particle pores, from periodically large pores to solid like materials with small voids.

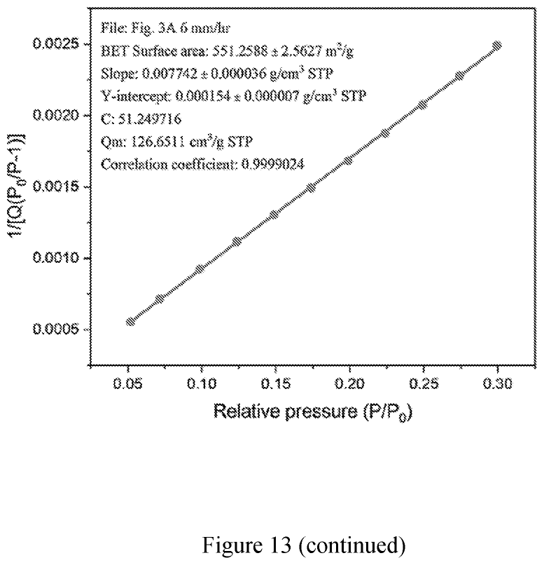

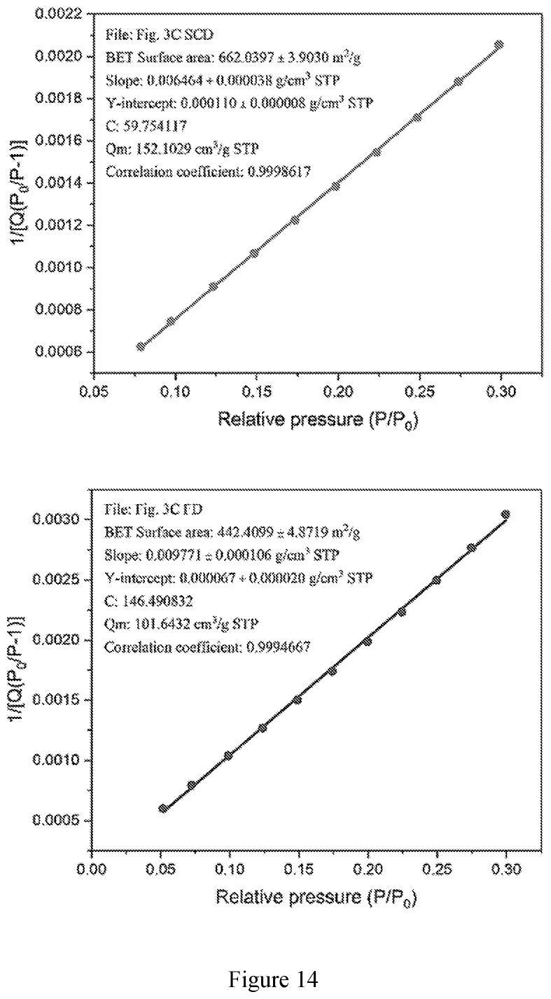

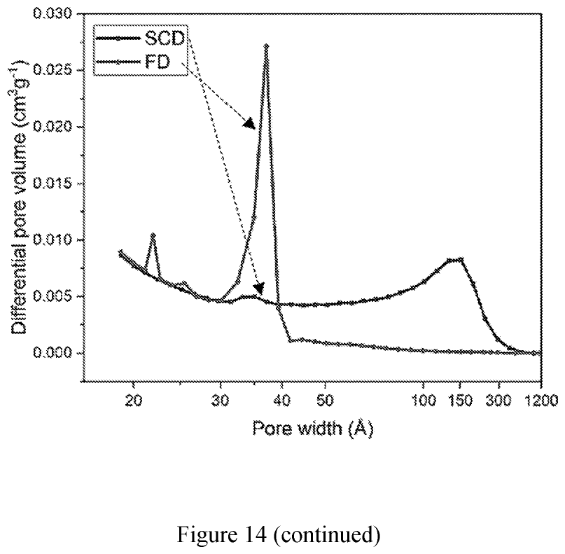

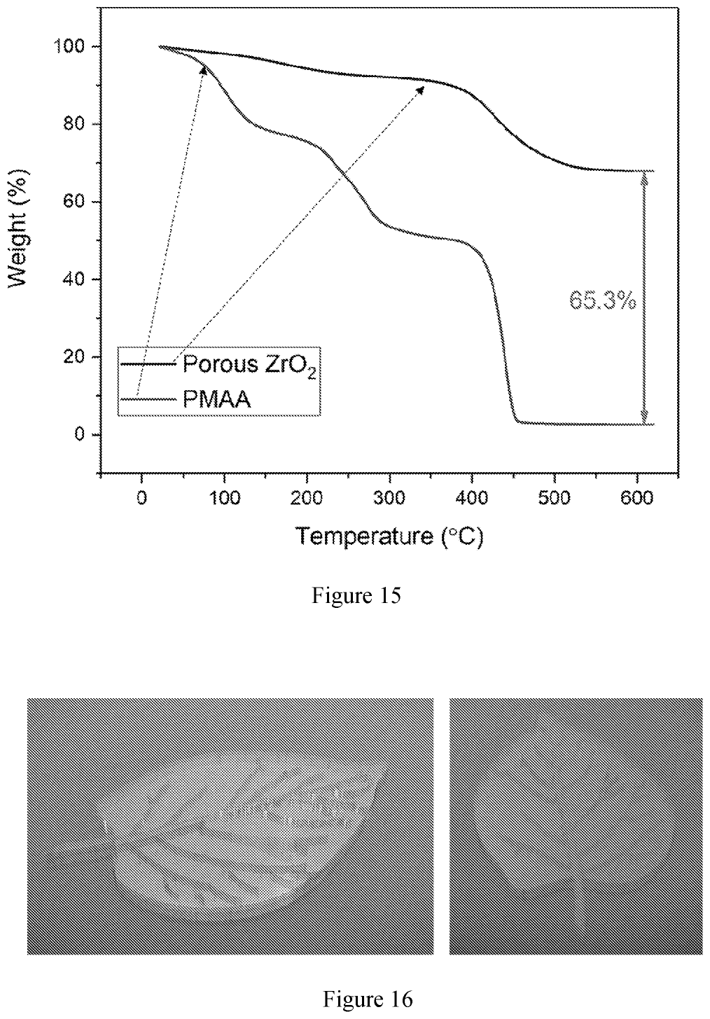

Removing the solvent without collapsing the internal pore structure presents a critical challenge in processing mesoporous materials. In the case of the 3D printed mesoporous structures at the focus of this paper, we found that freeze-drying contributes to the shrinkage of macroscopic structure due to the blockage of comparably fragile large pores. The loss in inter-particle pores around 20 nm is evidenced with narrow pore distribution at 3.7 nm and the lower BET surface area from 662 m²/g to 442 m²/g (FIG. 3C and FIG. 14). On the other hand, supercritical drying avoids the stresses arising due to capillary effects and helps to maintain the multi-level architecture. By drying the printed structures in a supercritical CO₂ dryer (see below for details), the collapse of the pore structure can be prevented and thereby form robust 3D printed structures without compromising the high internal surface area.

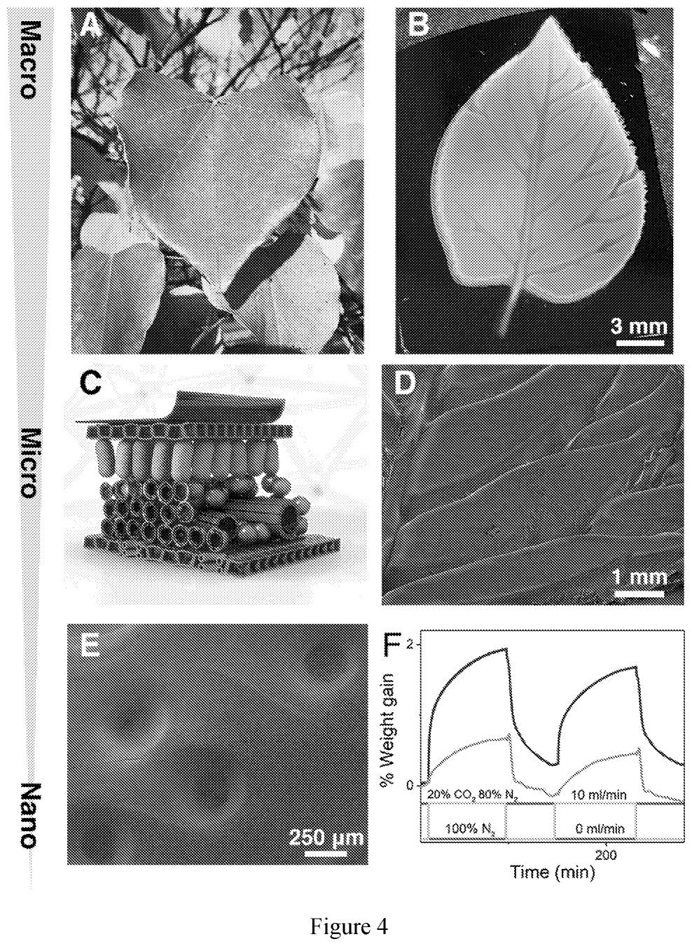

To underscore the practical utility of the mesoporous structures that can be fabricated using the method introduced in this paper, we demonstrate the proof-of-concept 3D printing of a highly porous leaf. In nature, the hierarchical porous structure of plant leaves has been refined through billion years of evolution to endow all levels of hierarchy from macropores for fluid and nutrient transportation, micropores for gas diffusion and nanopores for gas adsorption to perform complicated and optimal functionalities. In light of the inherent multi-functionality enabled by the hierarchical porous superstructure of natural leaves, a leaf, as shown in FIG. 4, was 3D printed. The designed leaf was 3D printed with macroscale vein-like channels in the middle layer, microscale stomata like pores only on the back surface and nanoscale spongy mesophyll cell-like voids. FIG. 4 indicates the printed features of both structure and functions in multilevel scale. The channels provide the similar function for mass transportation and the stomata is for gas diffusion. Furthermore, the thio-ene chemistry was employed to post synthesize the residual carbon double bond with cysteine (C₃H₇NO₂S), anchoring the amine group into the nanoscale pores. To underscore the ability of the artificial leaf to capture CO₂, the leaf was exposed to 20% carbon dioxide 80% nitrogen under 30° C. and 1 atmosphere. The nanoscale pores in inorganic leaf show the ability to adsorb up to 1.92 wt % carbon dioxide per gram of the leaf. Whereas the inorganic 3D printed leaf does not, yet, include the complex multifunctionality found in natural leaves (fluid transport, photochemical reaction, etc.), this structure nevertheless illustrates promising pathways to create programmable, 3D printed functional porous materials.

In summary, a straightforward, cost-efficient and fast route to process to fabricate hierarchical porous structures in a 3D printer was demonstrated. Demonstrated herein is the ability to harness both the nanoscale functionalities of porous materials and macroscale properties from the fabricated structure. The principle of PLIC design is expected to be applicable to different cores and ligands, which is a bottom-up avenue for nanomaterial fabrication.

Methods: Materials. All chemicals were purchased from Sigma Aldrich. Nitrogen and carbon dioxide were purchased from Airgas. The Si substrate was purchased from University Wafer. All materials were used as received without any purification.

Synthesis of PLIC. Zr₆O₄(OH)₄-MAA precursors were synthesized by adopting a sol-gel method as previously reported.

Additive manufacturing. PLIC ink was formulated by mixing PLIC nanoparticles, photoinitiator and solvent. For example, 150 mg of Zr₆O₄(OH)₄-MAA, 1 mg of photoinitiator, diphenyl(2,4,6-trimethylbenzoyl) phosphine oxide, were added into 1 ml of PGMEA. Inks were purged with nitrogen flow for 10 minutes before usage. Samples are printed with the homemade top-down digital light processing (DLP) 3D printer with 385 nm wavelength and intensity around 10 mW/cm². The general workflow involves slicing the desired 3D architecture into a series of images, which are then exposed as a sequence of UV patterns to define the cross section for each additive layer.

Activation and functionalization. All printed samples were washed with toluene. For supercritical carbon dioxide drying, samples were exchanged with methanol for 48 hours with renewing the solvent every 12 hours then dried in Leica CPD300 critical point dryer. As for freeze-drying, samples were immersed in cyclohexane for 48 hours with renewing the solvent every 12 hours. After frozen at −20° C. with three freeze-thaw cycles, the samples were dried with freeze dryer for 12 hours.

For amine-functionalized samples, dried samples were immersed in 3 ml methanol with 90 mg of cysteine for one day, then exposed to 254 nm UV light for 5 minutes. Samples were washed with methanol for several times and directly dried in hood.

General characterization methods. Powder x-ray diffraction characterization was carried out on Bruker-AXS D8 Discover Diffractometer using Cu K_{α} radiation at λ=1.54 Å by depositing powder on glass substrate. The FTIR was conducted on Bruker Hyperion FT-IR Spectrometer & Microscope. A background scan was collected before each measurement (64 scans), sample scan was an average of 64 scans, and resolution was set 4 with a data spacing of 0.482 cm⁻¹. Thermogravimetric analysis (TGA) were performed on a TGA Q500 (TA Instruments Inc.). The CO₂ capturing property of the artificial leaf was calculated based on the weight gain during the adsorption. The photo-rheometer test was done on DHR3, TA instruments with the light source Omnicure Series 1500. Parallel plate geometry with gap of 750 and the 365 nm filter with the controlled power being 10 mW/cm² were used.

Electron microscopes characterization. SEM images were acquired using Zeiss Gemini 500 SEM and Tescan Mira3 FESEM. STEM and TEM images were taken using FEI Tecnai F20 S/TEM. Printed samples were grounded into powders and tapped by the wafer or TEM grid for the imaging. PLIC nanoparticles were dissolved in toluene in the concentration of 5 mg/ml then drop coating onto the TEM grid. FIGS. 3D and E are the samples in FIG. 3A 6 mm/hr and 0.9 mm/hr respectively with supercritical drying and F is the sample in FIG. 3C with freeze-drying. Artificial leaf was processed with the gold sputtering before imaging.

Nitrogen-adsorption measurements. Nitrogen sorption isotherms were measured at 77k on Micromeritics ASAP 2460. Normally, tens of milligrams of printed samples were transferred into pre-weighed tubes. As for Zr₆O₄(OH)₄-MAA crystal, 100 mg of the material was added. All the samples were degassed under vacuum in room temperature for 2 hours before the test. The specific surface area and pore diameter were calculated using the Brumauer-Emmett-Teller (BET) and Barrett-Joyner-Halanda (BJH) method, respectively.

TABLE 1
Structuring method.

| Material | Method | S_{BET} (m²/g) | Shape Control | Dimension |
|---|---|---|---|---|
| Zr₆O₄(OH)₄- | 3D | 679 | O | cm scale 3D/2D |
| MAA PLIC | printing | | | film, structure |

RC = reaction confinement,
DG = direct growth,
CR = coordination replication.

TABLE 2
Digital light processing nanoparticle-related ink.

| Main compositions | Strategy | Usage |
|---|---|---|
| Zr₆O₄(OH)₄-MAA PLIC | Printable nanoparticle | Porous material |

The building units are conserved after the reaction and form highly porous materials. The red dot shows the scale of 2 nm as the comparison size with the building units.

FIG. 7 illustrates two possible mechanism by which PLIC ink is patterned during the processing. Mechanism I is a normal route to initiate and propagate the polymerization for photopolymer used in the 3D printer. Mechanism II is a proposed route for nanoparticle-based photoresist used in lithography; the second mechanism involves photoinitiated detachment of surface-bound ligands, which change the solubility of nanoparticles. In fact, the PLIC idea combine both the photoinitiator from mechanism I and similar nanoparticles from mechanism II. To better understand which mechanism is dominant, control experiments were performed and analyzed the mass distribution of products printed using PLIC inks. First, printed structures could not be obtained without adding photoinitiator, which suggests that mechanism I is dominant. Second, GPC analysis suggests that there are no fragments with mass larger than 1000 Da, indicating no long polymer chain in the samples. Therefore, it is proposed that the mechanism I is the main mechanism but some ligands may drop from the nanoparticles and participate in the propagate reaction when projecting 2D UV patterns.

FIG. 8 shows FTIR of Zr₆O₄(OH)₄-MAA before and after printing. The decreasing peak around 1600 cm⁻¹ shows the consuming of C═C, which supports the proposed mechanism.

FIG. 9 shows photo-rheometer for Zr₆O₄(OH)₄-MAA ink. The speed of the ink is measured by photo-rheometer. Gel point, the crossing point of storage module and loss module, is often used to calculate the minimum dosage needed to turn inks from liquid phase into solid phase. The ink shows the speed to print 750 atm thick monoliths in 10 seconds.

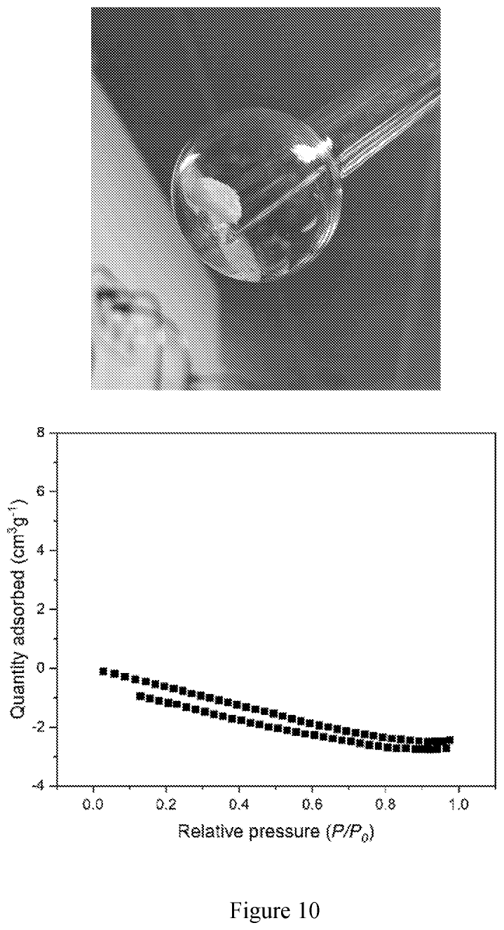

FIG. 10 shows nitrogen sorption isotherm for Zr₆O₄(OH)₄-MAA building units. The surface area of the building units was measured with nitrogen sorption isotherm in 77K. The result of 100 mg Zr₆O₄(OH)₄-MAA crystal shows very low surface area, indicating that pores are formed through the 3D printing process not the building unit itself.

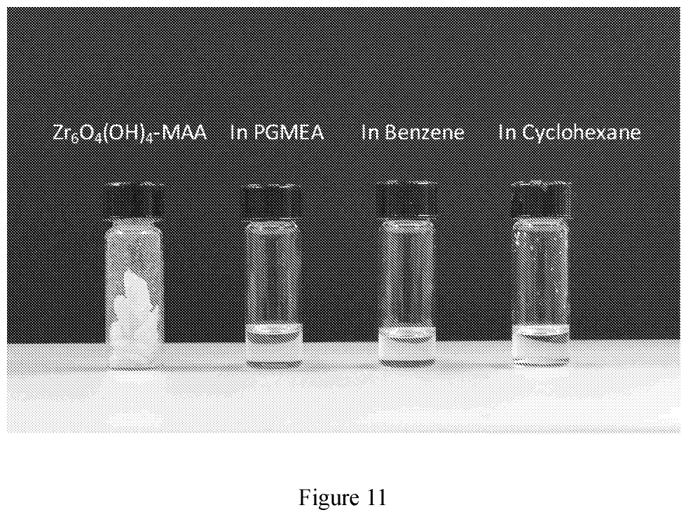

FIG. 11 shows solvent comparison for ink formation. Zr₆O₄(OH)₄-MAA crystal, solution of building units in PGMEA, benzene and cyclohexane are shown. For example, PGMEA and benzene are good solvents for the building units. However, building blocks are not soluble in solvent like cyclohexane, which makes assembly not printable.

FIG. 12 shows the effect of solvent chosen and processing conditions. Solvent chosen and processing are critical to conserve multi-level porous architectures. For example, shrinkage of the printed samples with direct drying make cracks in FIG. 12A. In addition, even the building units disperse well in the solvent like benzene, the printed samples exhibit more defects than using PGMEA as shown in FIG. 12B with supercritical drying and (C) with freeze drying. FIG. 12D to (F) demonstrates the surface area and pore-size distribution of FIG. 12C. The surface area decreases more than 50% compared with FIG. 3A.

### Example 2

The following example provides a description of compositions, methods, and articles of manufacture and uses thereof of the present disclosure.

Presented in this example are a class of building units, photoresponsive ligand on inorganic core (PLIC), to enable programming features and functions in extending length scale. The hypothesis is inherent properties from the inorganic core and organic ligand can be preserved if the combination on the molecular scale is considered. Taking nanoscale porosity, Zr₆O₄(OH)₄(MAA)₁₂ PLIC demonstrated formation of mesoporous materials in-situ during the process of connecting the building blocks into controlled shapes by UV light. This design harvest both superiorities of precise shape controlled from photopolymerization and atomically precise assembly from colloidal nanoclusters. Further, the programmability of functions and geometries were leveraged to fabricate bio-separation microfluidic devices. The designed mesoporous material was shown located in the channel with controlled patterns. In addition, the material was demonstrated with streptavidin, a glycoprotein consisting of four identical subunits, functionalization which possesses high binding affinity with biotin. The binding between biotin and streptavidin is one of the strongest non-covalent interactions and widely used for biotechnology such as drug delivery, biocatalysis, biosensing, and bioseperation. The immobilization of streptavidin shows the potential for biotechnology applications. Demonstrated is a simple and scalable method to fabricate mesoporous material with designed shapes and functions, which should be applicable to all kind of designed devices and important to commercial impact of related techniques.

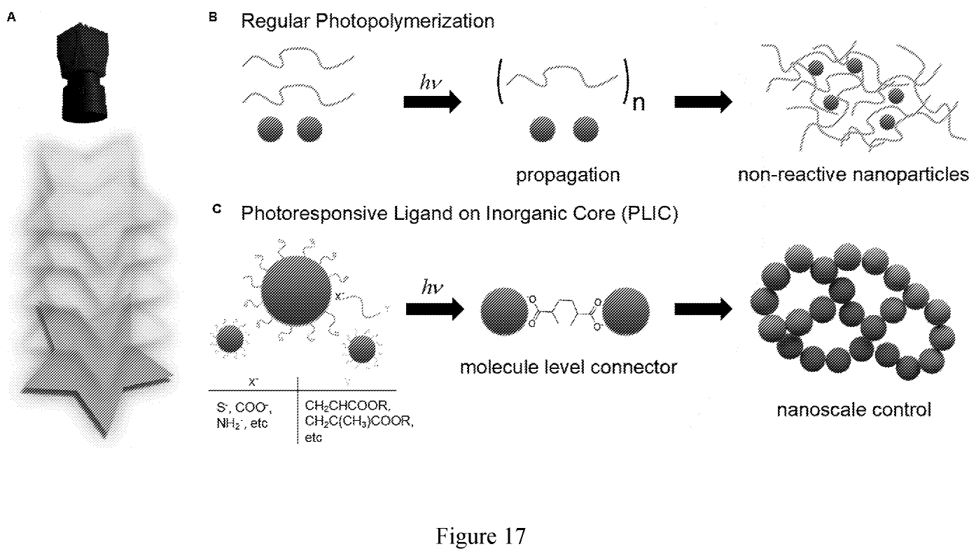

Results. The initial attempt to develop organic-inorganic nanocomposites was usually achieved by adding nanoparticles into photopolymer matrices (FIG. 17B). However, the propagation during photopolymerization leads to encapsulation of nanoparticles, which significantly limits the functions from inorganic nanoparticles. Therefore, nanoparticles are often treated as additives to enhance mechanical properties. In the PLIC design, the interaction between inorganic nanoparticles and photopolymerized monomer is manipulated at molecular scale. This strategy activates the role of inorganic nanoparticle and broadens the library of printable materials in photopolymerization.

There are several key components in the PLIC design as shown in FIG. 17C. First, the ligand is required to be a one site containing chelating group like thiol, carboxylic acid or amine to form coordination bond with the inorganic core. Besides, the ligands should possess photoresponsive end group like C═C from acrylate to be reacted as glue during processing. Second, properties of end product could be designed by properly selecting cores and ligands. For example, choosing different cores could generate distinct functionalities. In addition, the length of ligand could also affect the matter. Taking porous material as an example, long polymerized chain may lack mechanical hardness to support the cavity. To form nanopores, [Zr₆O₄(OH)₄]¹²⁺ was chosen as an inorganic core, which is demonstrated mechanically strong enough to form micro/mesopores and methacrylic acid as ligand, which is short and light sensitive. In this case, the photoresponsive ligands like methacrylic acid serve three functions: first to provide colloidal stability, second as a molecular connector by photopolymerizing the carbon double bond, and third active sites for additional functionalities.

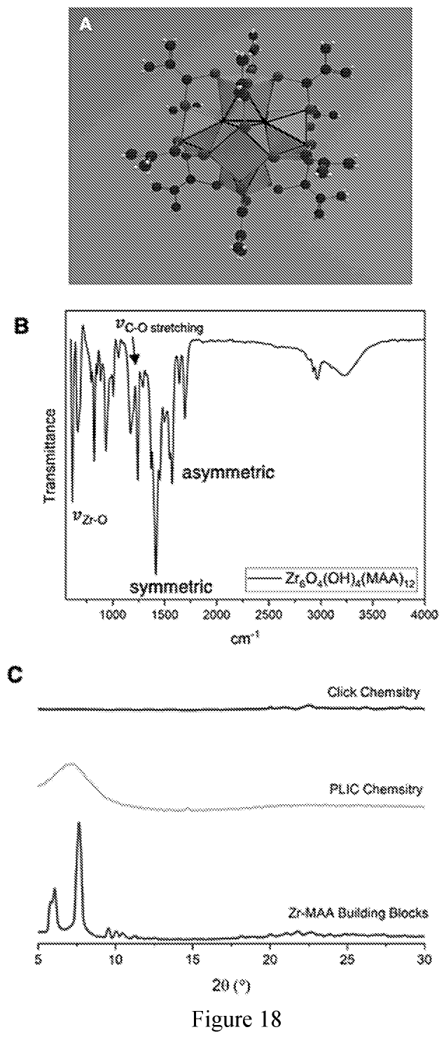

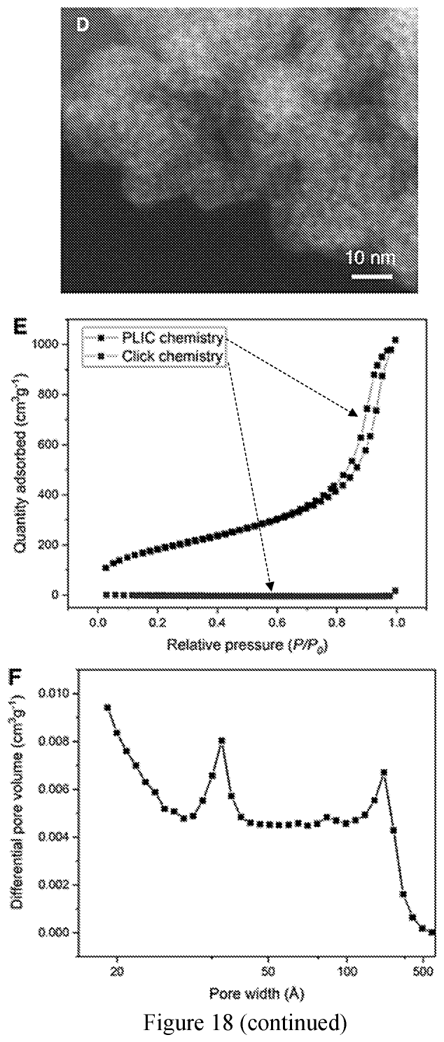

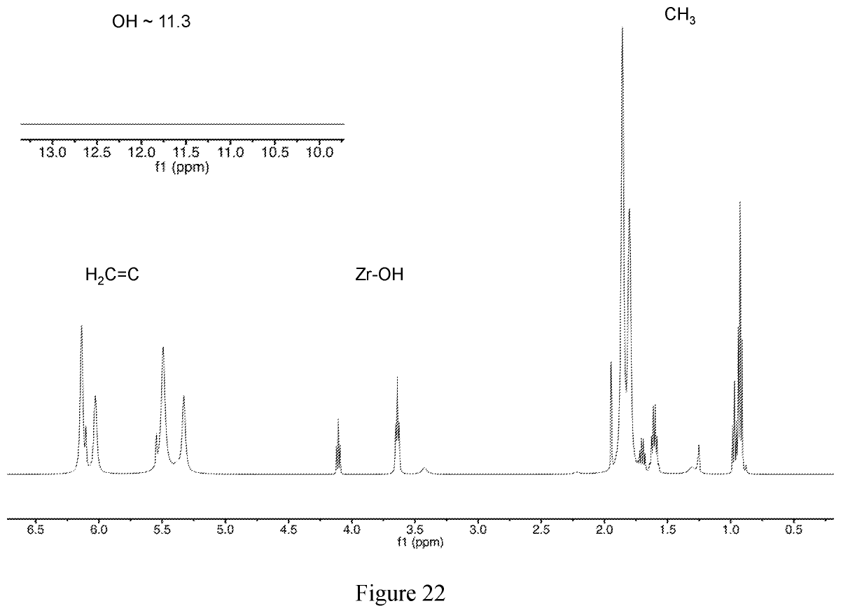

The structure of building block [Zr₆O₄(OH)₄](MAA)₁₂PLIC (Zr-MAA) extends from the prominent zirconium oxo cluster as shown in FIG. 18A. The building unit was synthesized by known methods. Powder X-ray diffraction (PXRD) pattern shown in FIG. 18C demonstrates that synthesized material remains crystalline and possesses feature peaks at 5.9° and 7.6°, being similar to the reported study. The compositions of Zr-MAA closely matches the composition of zirconium methacrylate obtained by Fourier transform infrared spectroscopy (FTIR) in FIG. 18B. The Zr—O vibration could be observed around 600 cm⁻¹. The symmetric and asymmetric COO⁻ vibrations show coordinated methacrylic acid to the Zr-oxide core. Furthermore, the ¹H NMR spectra for Zr-MAA is shown in FIG. 22, which is comparable to the literature. The signals at 6.14 and 5.55 ppm indicate the exist of C═C from methacrylate. In addition, the OH signal was not observed around 12 ppm, supporting the binding of the ligands. The discussed analyses back the conclusion of successfully synthesized Zr-MAA building blocks.

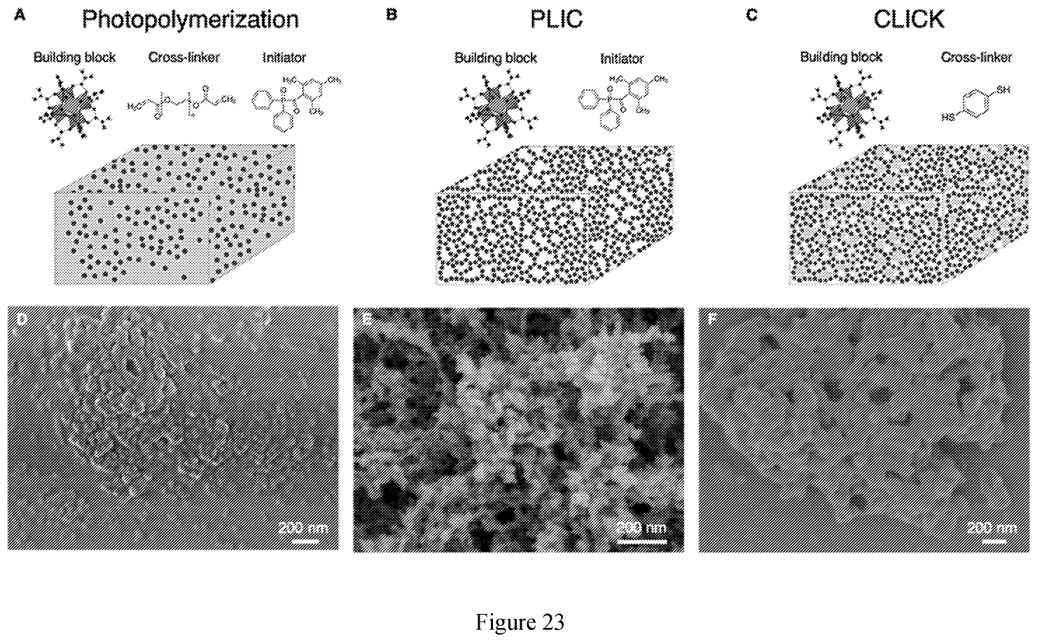

To implement PLIC chemistry, the ink was formulated by mixing the Zr-MAA building blocks with the free radical photoinitiator, but without any oligomer and cross-linker. The ligand on the core is used as the connector. From the transmission electron microscope (TEM) images shown in FIG. 18D, the building units were observed linked with each other and still remained the original size around 2 nm after reaction. Besides, the materials looked semi-transparent because of the porosity. The signals of building units detected in PXRD with reacted samples also support the preserve of building blocks though losing some crystalline as shown in FIG. 18C. In addition to the small nanopores, large nanopores were observed from the scanning electron microscope (SEM) image of reacted sample as shown in FIG. 23E. To further unveil the porosity of connected Zr-MAA, the nitrogen sorption measurement was done as shown in FIG. 18E. The reacted sample exhibits the Brunauer-Emmett-Teller (BET) surface area with 675 m² g⁻¹ (Langmuir surface area: 1036 m² g¹) and Barrett-Joyner-Halenda (BJH) theory calculation of 3.7 nm and 18 nm pore size domination, matching the results from electron microscopes. The cause of large mesopores is similar to aerogel and pore around 20 nm is also observed in previous work using [Zr₆O₄(OH)₄]¹²⁺ cluster to form hierarchical porous materials. The assumption of connecting selected Zr-MAA PLIC to form nanoscale porous material is confirmed by the above characterizations.

Two different chemistries to connect building blocks were compared, including normal photopolymerization and thiol-ene click (FIG. 23). For the normal photopolymerization, the building block was seemed as monomer and mixed with poly(ethylene glycol) diacrylate (PEGDA) and free radical photoinitiator. This formulation is similar to the common photopolymer. After cross-linked by UV light, the sample became solid without nanoscale features such as porosity and aggregation of building units could be observed through the SEM image (FIGS. 23A and D). The cross-linker may be too long in length to strut the formation of pores. In addition to free radical photopolymerization, click chemistry was also tried to connect the building blocks. The thiol-ene click chemistry is a reaction between thiol (SH) with C═C bond triggered by UV irradiation. The ink was formulated by Zr-MAA building blocks and benzene-1,4-dithiol as cross-linker without any photoinitiator. The reacted sample looks like the mixture of photopolymerization and PLIC, not completely solid but losing the molecule-level features. The building units seemed damaged and fused together as shown in FIG. 23C. Ligand exchange may happen between the cross-linker and methacrylic acid since thiol is also an attractive ligand. The PXRD study in FIG. 18C supports that signal of Zr-MAA could not be detected after thiol-ene click reaction. Further, the BET surface area measured from nitrogen sorption also indicates very low porosity as shown in FIG. 18E.

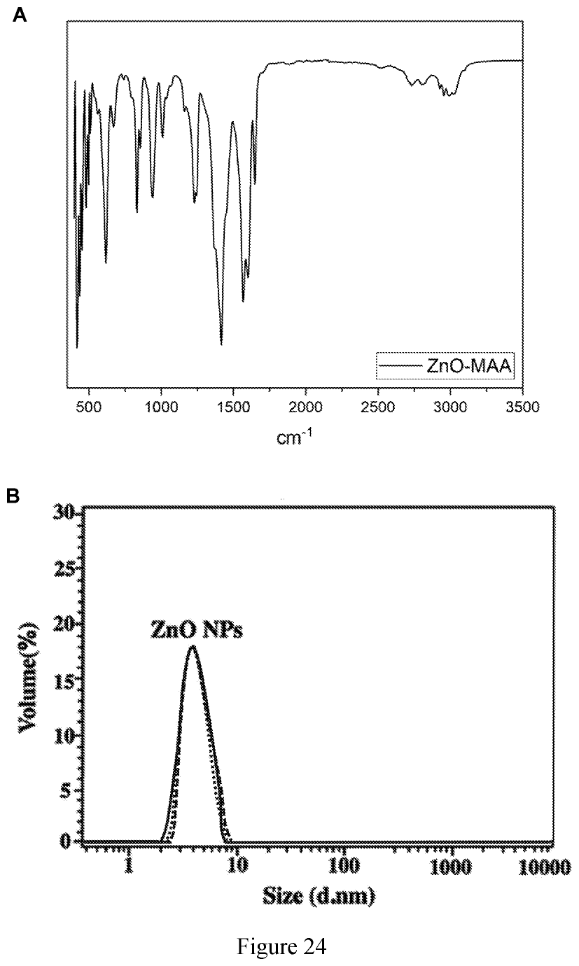

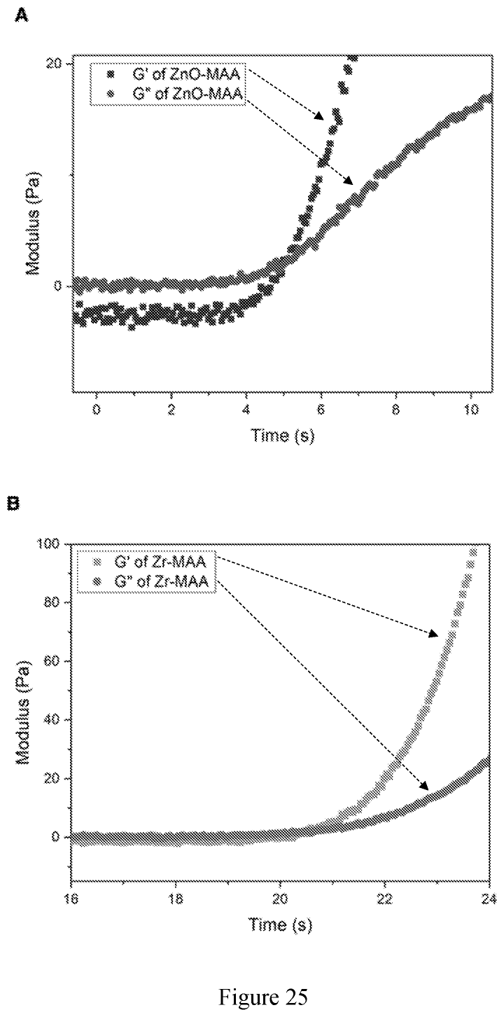

The functionality of different PLIC cores was also studied. ZnO-MAA PLIC was synthesized by changing the core to ZnO but using the same methacrylic acid ligand. The composition of ZnO-MAA was evidenced by FTIR and dynamic light scattering (FIG. 24). The film could be reacted into a controlled shape by the ink composed of ZnO-MAA PLIC and photoinitiator without any other crosslinker or oligomer (FIG. 24). The ZnO has been shown to be active photoinitiator in the free radical polymerization, so it was expected ZnO-MAA should possess better kinetics. As expected, the kinetics of ZnO-MAA PLIC reaction is 4 times faster than Zr-MAA investigated by photo-rheometer (FIG. 25). The result demonstrates the PLIC chemistry can work for different combination of core and ligands, can be used to diversify material compositions for photo-triggered reactions.

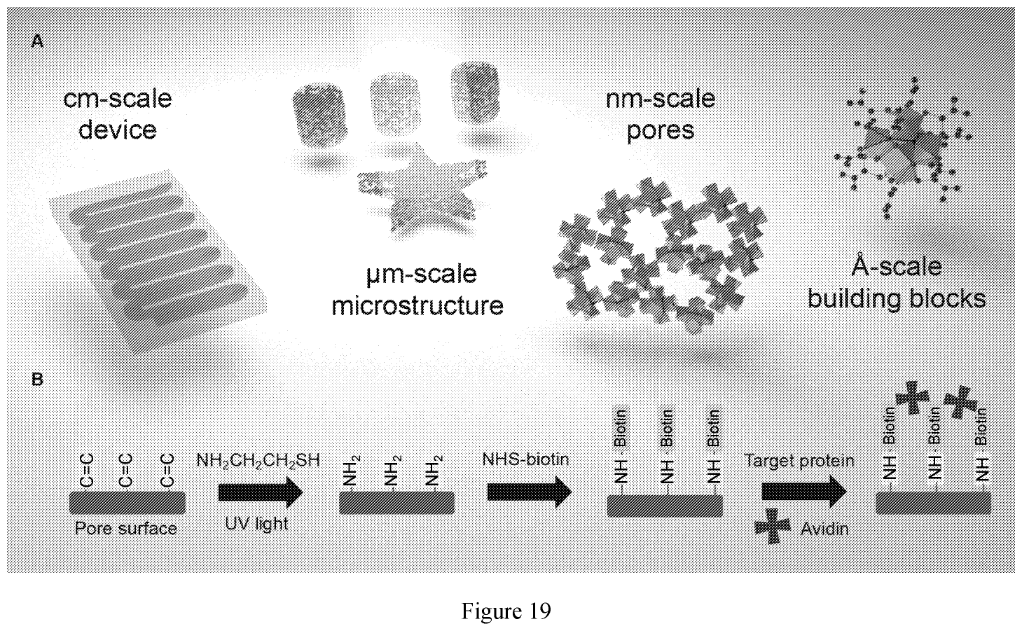

The mesoporous material formed from Zr-MAA PLIC has can be a platform for different applications such as protein separation, biocatalyst templating and so on because the ease of processability and design of multi C═C in the building units as shown in FIG. 19A.

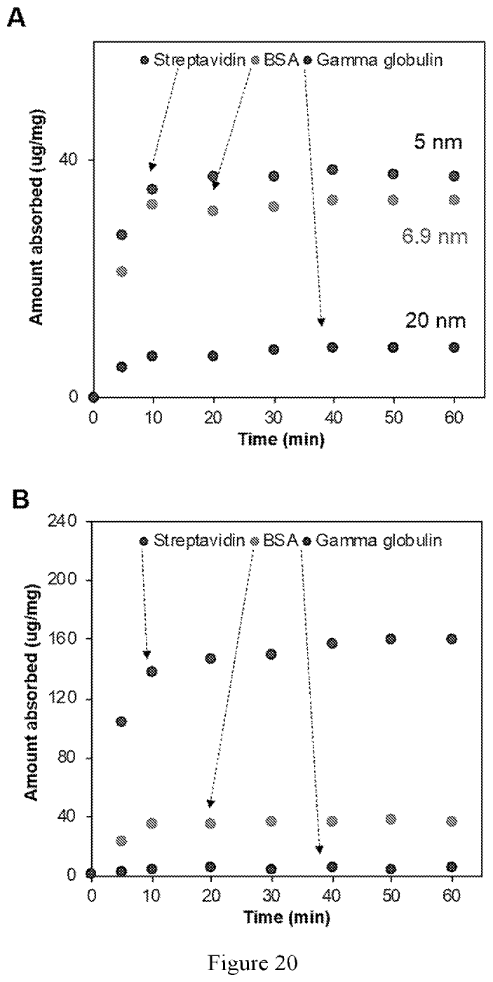

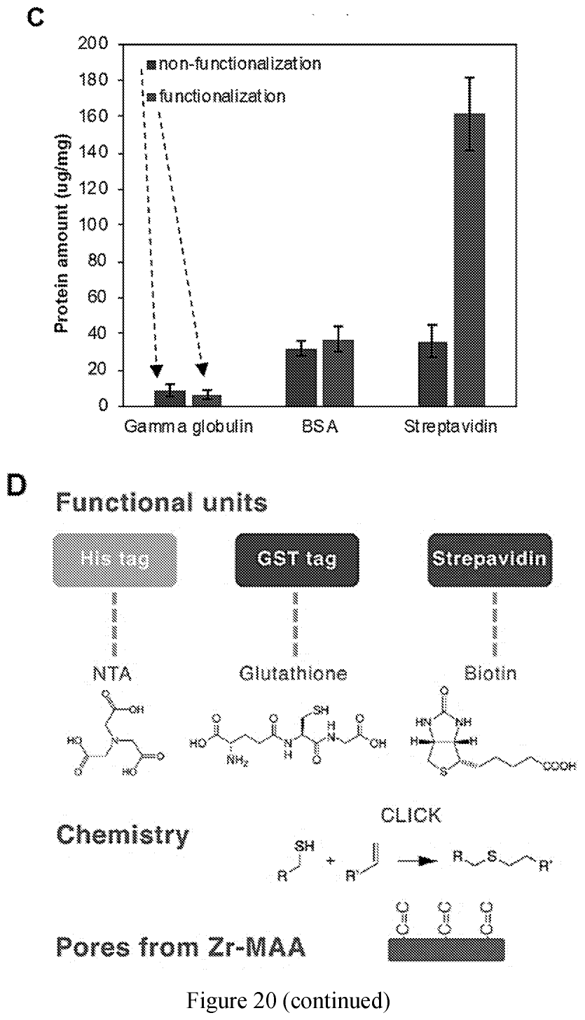

Liquid-phase adsorption experiments were first performed to explore the accessibility of printed mesopores from Zr-MAA towards different sizes of molecules. Streptavidin (SA, 53 kDa, D=5 nm), bovine serum albumin (BSA, 67 kDa, D=6.8 nm), and immunoglobulin-γ (IgG, 150 kDa, D=20 nm) were selected as the probe molecules. The bovine serum albumin and immunoglobulin-γ are the common blood proteins with different molecular weights and hydrodynamic diameter. Immunoglobulin-γ is even the major antibody used in immunological study and clinical diagnostics. Streptavidin with high biotin affinity is widely used in biotechnology application. As shown in FIG. 20A, non-functionalized mesoporous material almost cannot adsorb gamma globulin from aqueous solution, but can accommodate streptavidin and BSA, which have smaller size. This phenomenon can be explained by the size exclusion from the mesopores. The molecular weight of gamma globulin is around 3 times larger than streptavidin and BSA and is in the similar size to the mesopores, which make it hard to pass into the pores.

In addition to size exclusion from pores, the pore surface can be tuned in molecular level by reacting the left C═C because not all the methacrylate groups participate in the linking reaction. Notably, multifunctional surfaces that interact with biological system at the molecular level are in great demand. To demonstrate the accessibility and usability of the C═C, the pore surface was functionalized with biotin to show immobilization of streptavidin. The biotin functionalization is performed by the reaction between amine group and N-hydroxysuccinimido biotin (NHS-biotin) (FIG. 19B). As shown in FIG. 20B, the absorption capacity of BSA and gamma globulin remain similar as non-functionalized material. However, the significant increase of streptavidin absorbed and captured indicates the specific streptavidin-biotin binding with the functional pore surface. FIG. 20C concludes the capacity of mesoporous materials formed from Zr-MAA for different proteins. The concept of functionalizing the surface for protein immobilization can be applied to more pairs like Ni-NTA to His-tagged protein or glutathione to GST-tagged protein (FIG. 20D).

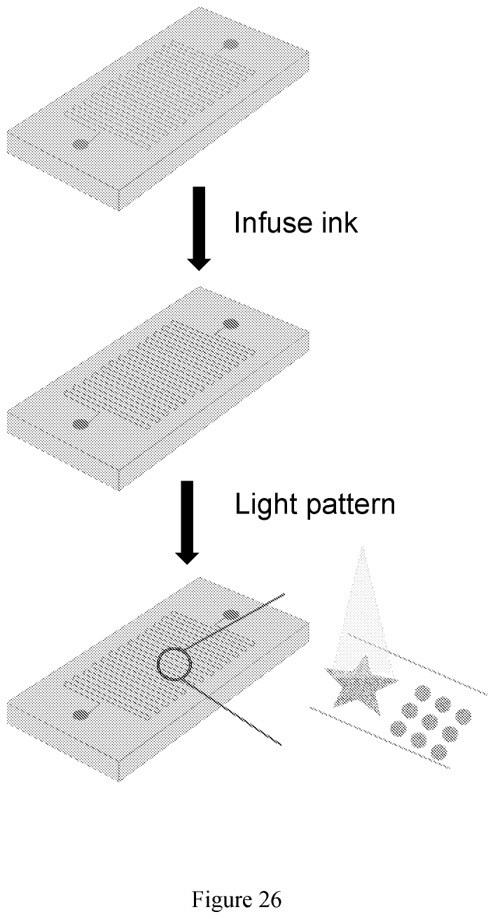

The above experiments show the ability to program the Zr-MAA PLIC into functional mesoporous materials for bio-separation. As the next step, the advantage of processability was leveraged to fabricate mesoporous materials inside microchannels with controlled morphology and location as devices for bio-application. The overall steps are shown in FIG. 26.

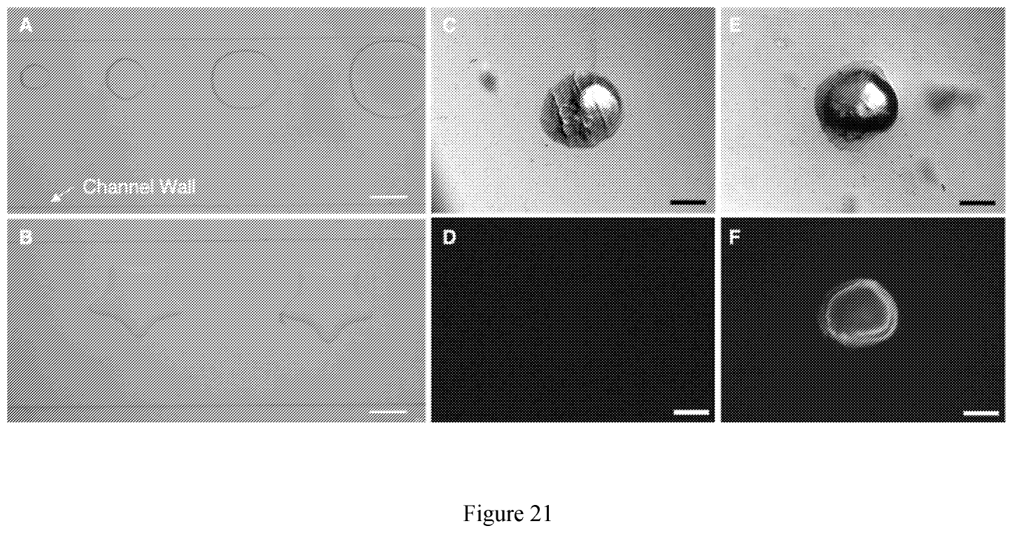

Since the PDMS is UV-light transmittable, the chips would not significantly eliminate the photons. Considering the accessibility, a projector was used as the maskless light source instead of photolithography, a process for microfabrication by using photomask to generate shapes on the substrate, because of expensive clean-room equipment and time-consuming steps needed for the acquisition of photomask. The patterns can be designed and changed easily without extra-cost. The control of geometry and position is shown with an array of circles from 150 μm to 400 μm and stars as shown in FIGS. 21A and B. The printed mesoporous structures possess 10 times higher surface area compared with traditional free radical polymerized porous monoliths in the microfluidic devices. The extending surface area could provide the advantages of improving the separation efficiency of small and macromolecule, catalytic reaction of immobilized enzyme, biosensing capacity of a minimized device. In addition, the microfluidic device could perform various functions by introducing different designed patterns. The function of microfluidic devices printed with Zr-MAA PLIC were demonstrated, as shown in FIG. 21C to F. The fluorescence signals support the functionalization of biotin on pore surface and immobilization of streptavidin-488 Alex Fluor inside the mesoporous microstructures in the microfluidic channel (FIGS. 21E and F). No observation of fluorescence signals in the control experiment (FIGS. 21C and D).

In summary, the PLIC concept harvests both the functionalities of inorganic nanoparticles and processability of organic monomer for opportunities for fabrication of devices and extends the potential of microfluidics as minimized bioreactors, point of care diagnosis, and biosensors.

METHODS. Materials. Nitrogen and carbon dioxide were purchased from Airgas. The Si substrate was purchased from University Wafer. Bicinchoninic acid (BCA) protein assay kit and N-hydroxysuccinimidobiotin (NHS-biotin) were obtained from Thermo Fisher Scientific. All other chemicals were purchased from Sigma Aldrich except mentioned. All materials were used as received without any purification.

Synthesis of PLICs. Zr-MAA: Zr₆O₄(OH)₄-MAA precursors were synthesized by adopting the method as previously reported. Briefly, Zr isopropoxide was dissolved in excess of methacrylic acids at 65° C. followed by the slow addition of a water/methacrylic acid mixture. It was left to react for 21 h, and the product was precipitated in water centrifuged at 8000 rpm. The final product was dried under vacuum overnight.

Zn-MAA: ZnO and MAA were slowly added to ethyl acetate with stirring in the dark to produce a milky dispersion. ZnO—NPs were prepared using a method similar to that employed to synthesize HfO₂- and ZrO₂-based NPs. The dispersion was allowed to continuously stir for 7 days; the color of the solution gradually changed from milky white to transparent light yellow as the ZnO-MAA NPs became uniformly distributed in the EA solvent. The EA solvent was then removed at 70 mmHg; orange ZnO-MAA NPs remained.

Ink Formulation. PLIC ink was formulated by 150 mg of dried Zr-MAA cluster and 1 mg of photoinitiator, diphenyl(2,4,6-trimethylbenzoyl) phosphine oxide, in 1 ml toluene (ink 1). Ink for normal photopolymerization was formed by mixing dried 150 mg of Zr-MAA cluster, 500 μL of poly(ethylene glycol) diacrylate (PEGDA) and 1 mg of the same photoinitiator in 500 μL toluene (ink 2). Ink for thiol-ene click was formulated by 150 mg of dried Zr-MAA cluster and 150 mg of benzene-1,4-dithiol in 1 ml of toluene (ink 3). Ink for Zn-MAA was formulated by 150 mg of dried ZnO-MAA nanoparticles and 1 mg of the same photoinitiator in 1 ml toluene (ink 4). The films formed from ink 1, 2 and 4 were made under exposure of 385 nm UV light from the projector (10 mW/cm²). The film formed from ink 3 was reacted under UV lamp (UV-C).

Device Fabrication. The generation of microchannel silicon mold developed using soft lithography was published previously. Each microfluidic device contained six channels. The dimensions of each channel are 1 mm wide by 70 μm deep with a total length of the channel of 1.5 cm. Microfluidic devices were formed using PDMS in a molding process. The silicon mold was coated with Sigmacote via vapor deposition to facilitate the release of cured PDMS. A 10:1 (elastomer/crosslinker) mixture of Sylgard 184 (Dow Corning) was mixed and then degassed before pouring on the silicon master slide etched with the flow cell pattern. The PDMS was then baked for 3 h at 80° C. Glass coverslips (25 mm×25 mm; No. 1.5) from VWR were cleaned in piranha solution (45 ml 50% hydrogen peroxide and 105 ml 70% sulfuric acid) for 10 min then rinsed 30 min with deionized water. Glass coverslips and PDMS were first treated with oxygen plasma using a Harrick Plasma Cleaner (Model #PDC-32G; Harrick, Ithaca, N.Y.) at a pressure of 750 millitorr on the “high” setting for 15 s. The two pieces were assembled together, and annealing was performed at 80° C. for 15 min.

Characterization. Printed samples were washed with toluene and methanol for several times. Supercritical carbon dioxide drying, Leica CPD300 critical point dryer, is used to dry samples for characterization. Powder x-ray diffraction characterization was carried out on Bruker-AXS D8 Discover Diffractometer using Cu K_{α} radiation at λ=1.54 Å by depositing powder on glass substrate. The FTIR was conducted on Bruker Hyperion FT-IR Spectrometer & Microscope. A background scan was collected before each measurement (64 scans), sample scan was an average of 64 scans, and resolution was set 4 with a data spacing of 0.482 cm⁻¹. Dynamic light scattering (DLS) (Zetasizer Nano 90; Malvern, Worcestershire, UK) was used to measure the hydrodynamic diameter of NPs dispersed in the solvent. SEM images were acquired using Zeiss Gemini 500 SEM. STEM and TEM images were taken using FEI Tecnai F20 S/TEM. Printed samples were grounded into powders and tapped by the wafer or TEM grid for the imaging. Zr-MAA nanoparticles were dissolved in toluene in the concentration of 5 mg/ml then drop-coating onto the TEM grid. Nitrogen sorption isotherms were measured at 77k on Micromeritics ASAP 2460. Normally, tens of milligrams of printed samples were transferred into pre-weighed tubes. All the samples were degassed under vacuum in room temperature for 2 hours before the test. The specific surface area and pore diameter were calculated using the Brumauer-Emmett-Teller (BET) and Barrett-Joyner-Halanda (BJH) method, respectively. The photo-rheometer test was done on DHR3, TA instruments with the light source Omnicure Series 1500. Parallel plate geometry with gap of 500 μm and the 365 nm filter with the controlled power being 10 mW/cm² were used.

Functionalization of materials/devices. For amine-functionalized samples, dried samples were immersed in 3 ml methanol with 90 mg of cysteine for an hour, then exposed to UV light for 5 minutes. Samples were washed with methanol for several times and directly dried in hood.

For biotin-functionalized samples, the sample were further immersed in 20 mg/ml NHS-biotin solution in DMF under room temperature for 12 hrs. Samples were washed with DMF for several times and then washed with PBS for several times.

For streptavidin affinity experiment in microfluidic device, channel was first blocked with BSA for preventing non-specific binding to surface. The streptavidin-Alexa Fluor 488 at 0.2 mg/ml were incubated with printed material in channel for 1 hr at room temperature. Then, the channel was rinsed with PBS to remove the unbound streptavidin-Alexa Fluor 488. The images were recorded by inverted Zeiss Axio Observer.Z1 microscope with a Plan-Apochromat 20× objectives.

Determination of Protein Adorption/Capture Capacity. Bovine serum albumin (BSA), gamma globulin, and streptavidin were added into phosphate buffered saline (PBS) buffer separately at 0.2 mg/ml. Then, 5 ml of solution were incubated with 2 mg non-functionalized or functionalized material for 1 hr at room temperature. The concentrations of supernatants before and after incubation were analyzed by bicinchoninic acid (BCA) assay to determine the amount of protein absorption to material and specific avidin binding to biotin-functionalized material.

Functions of different PLIC cores. Characterization of synthesized ZnO-MAA PLIC were done with FTIR and dynamic light scattering as shown in FIG. 24. The UV curing rate of different PLIC inks are measured by photo-rheometer. Gel point, the crossing point of storage module and loss module, is often used to calculate the minimum dosage needed to turn inks from liquid phase into solid phase as shown in FIG. 25.

### Example 3

The following example provides a description of compositions, methods, and articles of manufacture and uses thereof of the present disclosure.

Small molecule impurities, such as N-nitrosodimethylamine (NDMA), have infiltrated the generic drug industry. Described in this example is a solution that addresses these challenges by leveraging the assembly of atomically-precise building blocks into hierarchically porous structures. A bottom-up approach was introduced to form micropores, mesopores, and macroscopic superstructures simultaneously using functionalized oxozirconium clusters as building blocks. Further, photopolymerization was leveraged to design macroscopic flow structures to mitigate backpressure. Based on these multi-scale design principles, simple, inexpensive devices that are able to separate NDMA from contaminated drugs were engineered. Beyond this system, this design strategy is expected to open up hitherto nanomaterial superstructure fabrication for a range of size-exclusion purification strategies.

These findings demonstrate hierarchical control over microscopic porosity, mesoscale assembly, and macroscopic superstructures, which leads to new materials exhibiting efficient mass transport and selective adsorption of NDMA. Directional connection of colloidal building blocks at the molecular level to generate micropores was observed. The formation of sub-nm pores was validated by demonstrating the removal of NDMA from the drug Irbesartan. This technique enables control of pore size on the angstrom level as an alternative to the recent focus on tuning chemical functionalities to separate species by polarity. The underlying relationship between processing (cluster concentration), structure (pore size distribution), and performance (size-selective separation) was elucidated to produce next-generation hierarchically porous materials.

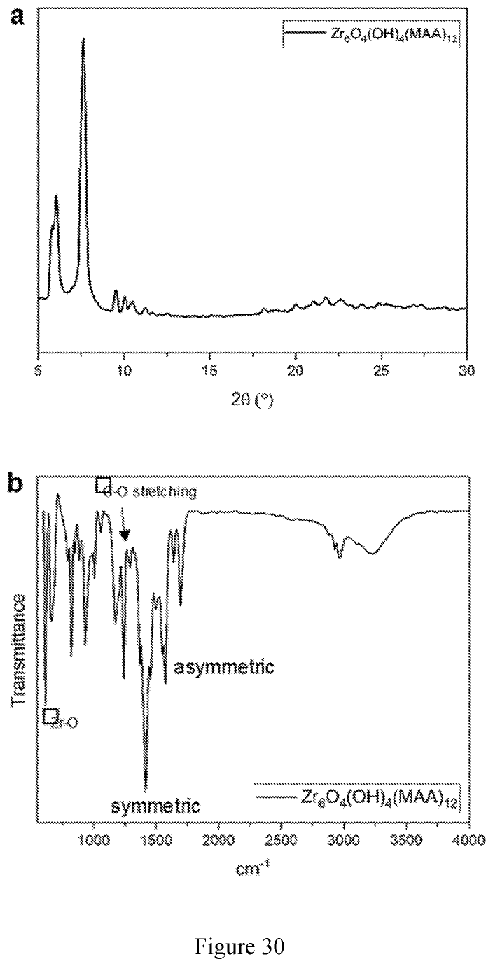

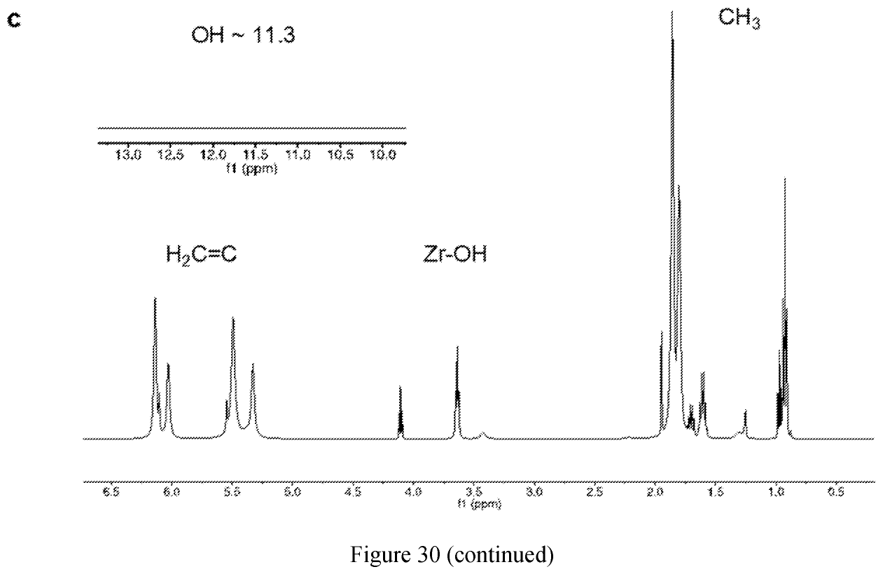

Results and Discussion. The Zr₆ methacrylate-functionalized cluster Zr₆O₄(OH)₄(MAA)₁₂ (Zr-MAA) was employed as a colloidal building block to prepare hierarchical micro/mesoporous materials. The characterization of Zr-MAA is summarized in FIG. 30. After synthesis, Zr-MAA was prepared as a photoresponsive ‘ink’ by dissolving into toluene along with a photoinitiator (diphenyl(2,4,6-trimethylbenzoyl) phosphine oxide). Exposing this formulation to UV light triggers polymerization of the methacrylate groups and forms robust connections between constituent building blocks. When combined with (digital) light patterning and additive manufacturing strategies, this approach can form arbitrary shapes by moldings or patterned UV light sources. In an important distinction from prior work regarding coordination polymers, the building blocks were designed based on monodentate ligands ending with photoresponsive groups (C═C) instead of active chelating groups. The reaction was photoinitiated in a subsequent step to form micropores, mesopores, and macroscopic structures in a single step. Therefore, the colloidal Zr-MAA nanoclusters are stable and processable in solvents before any pores have formed. The materials fabricated using this approach share some similarities with porous coordination polymers (PCP). For PCP, micropores are formed first via the connection of multidentate organic linkers with inorganic cores, which then react further to form larger structures. However, the inherent fragility limits the synthesized micropores to powdered form, leading to notoriously challenging processing.

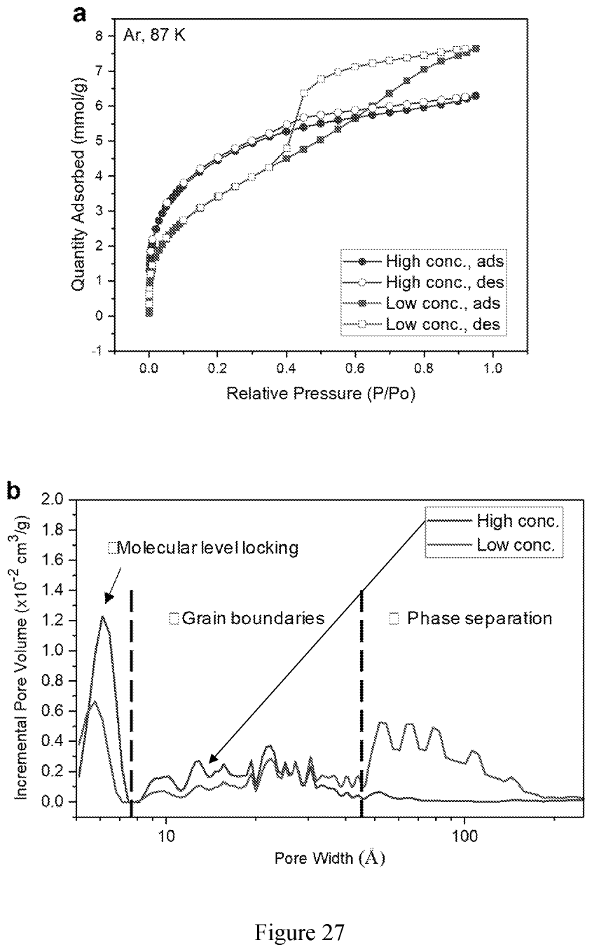

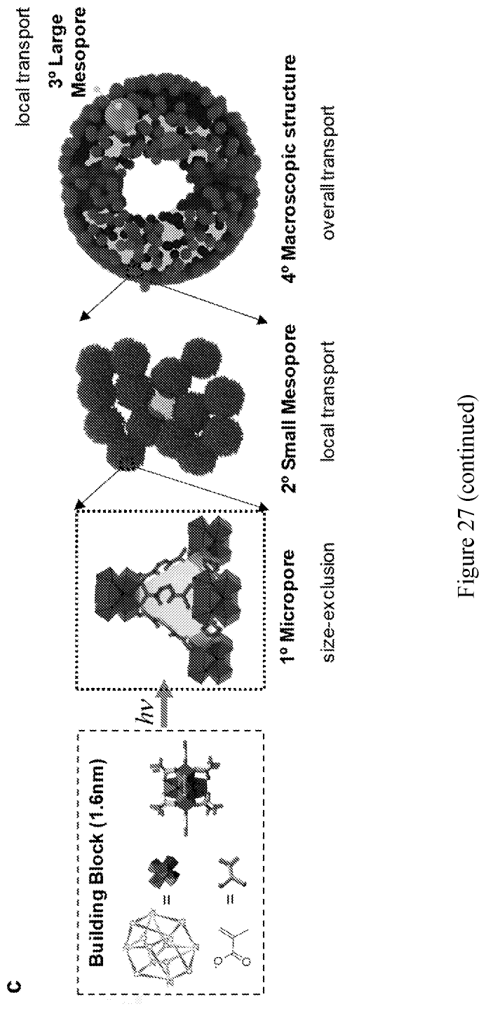

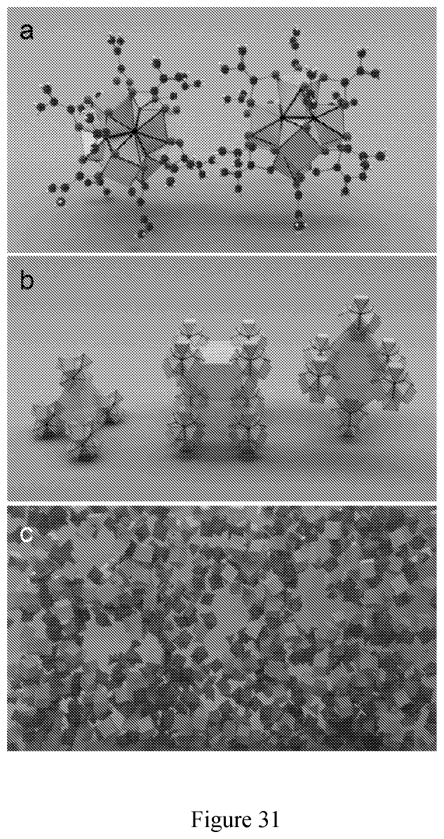

The pore size distribution was analyzed using Ar gas adsorption (FIG. 27). The step-like desorption behavior of the isotherm in FIG. 27a is indicative of mesopores within the material. FIG. 27b shows the hierarchy of pore sizes spanning from Å sized micropores (region I), several nm (region II) to tens of nm (region III) sized mesopores. The first distribution is in the micropore regime (6 Å), most likely arises due to the connection of building blocks similar to the structure of the PCP UiO-66. Importantly, the observed micropores unveil an unreported chemistry to utilize acrylate monomer ligands to oriented attach inorganic nanoparticles, which is different from bulky photopolymerization. The 6 Å pores can be referred to as tetrahedral cages similar to the tetrahedral cages of UiO-66; however, the formation of octahedra cannot be ruled out. The kinetics to form tetrahedral cages are inferred to be faster than forming octahedral cages, so the building units incline to stack into tetrahedra (FIG. 31).

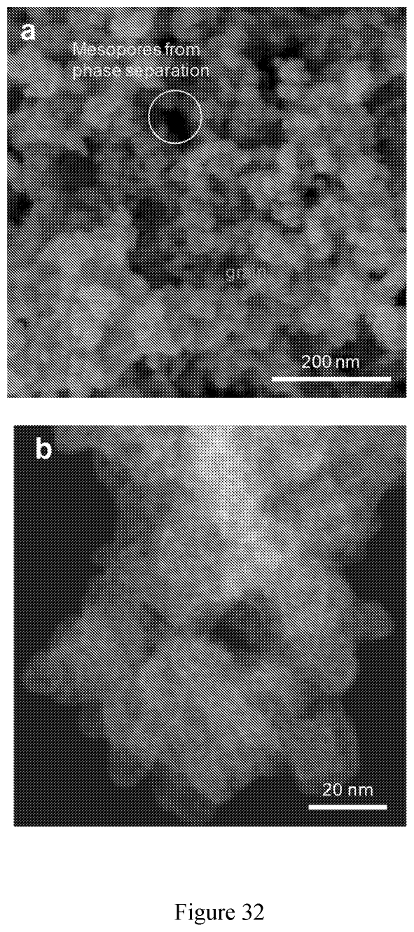

The second pore-size distribution is around 2-3 nm. These pores are attributed to the space between superclusters of linked tetrahedra; the superclusters visible in scanning electron microscopy images are around tens of nanometers in diameter (FIG. 32). The distribution of sub-nm pores (within the tetrahedron) and nm pores (between the superclusters) hence reflects the nucleation and growth conditions. The growth of Zr-MAA nanoclusters into a single, large crystal is difficult because of the relatively fast kinetics and irreversibility.

The third pore-size distribution is in the range of ten nanometers, which is attributed to phase separation behavior during material processing. Large mesopores like the ones formed here have been previously observed using the same [Zr₆O₄(OH)₄]¹²⁺ cluster under hydrothermal conditions.

The relationship between the broad spectrum of pore sizes is schematically summarized in FIG. 27c. It is shown that the pore-size distribution can be adjusted by changing the building block concentration. It is hypothesized that this processing-structure relationship derives from the underlying nucleation and growth dynamics of the tetrahedra and superclusters. A high concentration of building blocks leads to enhanced nucleation of superclusters whereas low concentration of Zr-MAA leads to less nucleation and more growth to form larger superclusters and hence a more dominant contribution of nm pores in the final material. The ability to control hierarchical porosity can mitigate mass transfer limitations, increasing the likelihood of small molecule adsorption in the micropores.

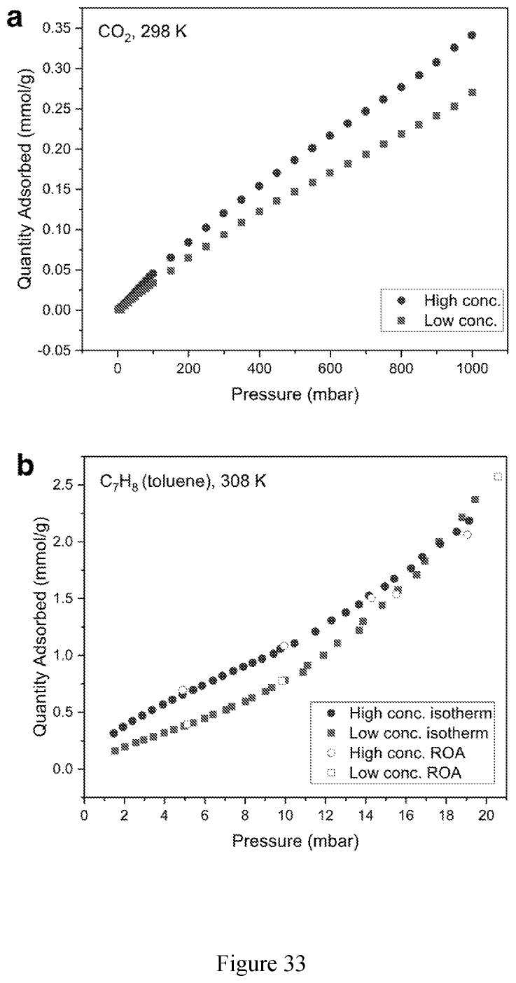

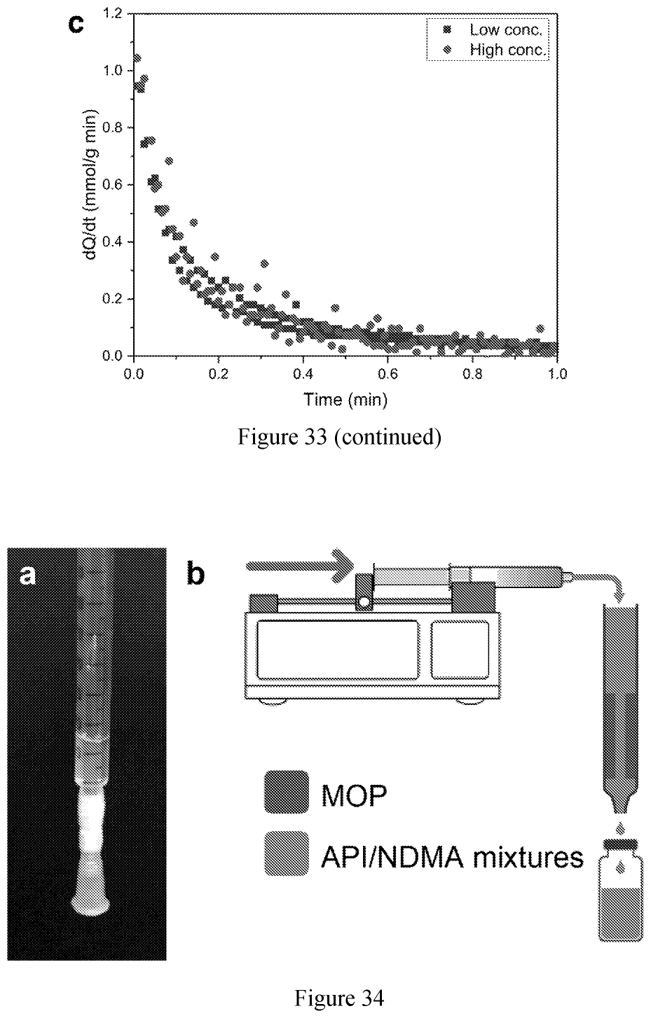

To further validate the permanent porosity and utility of pores for size-selective separations, the adsorption of different gases was probed. Carbon dioxide (˜2-3 Å) uptake was measured (FIG. 33a). The result confirms that the sample made from a high concentration of Zr-MAA can uptake more CO₂ because of more micropores. However, both of the samples possess relatively low CO₂ capacity (<0.4 mmol/g) due to the absence of strong CO₂ binding sites. Complementary gas uptake experiments with toluene (˜5-6 Å) conducted reveal a gas uptake (˜3 mmol) that is seven times higher compared to CO₂. Toluene interacts more strongly with the pore walls than CO₂, so it can likely be trapped more strongly within the 6 Å micropores (FIG. 33b).

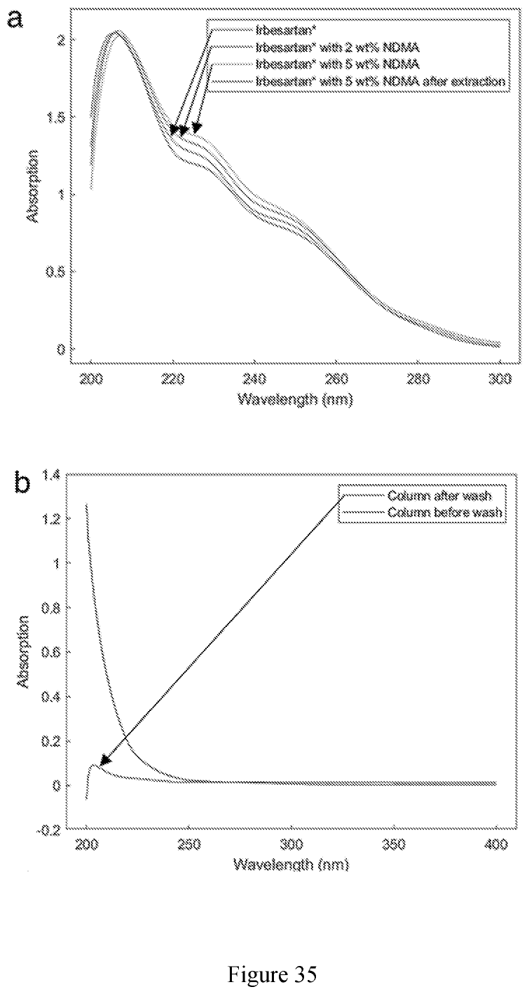

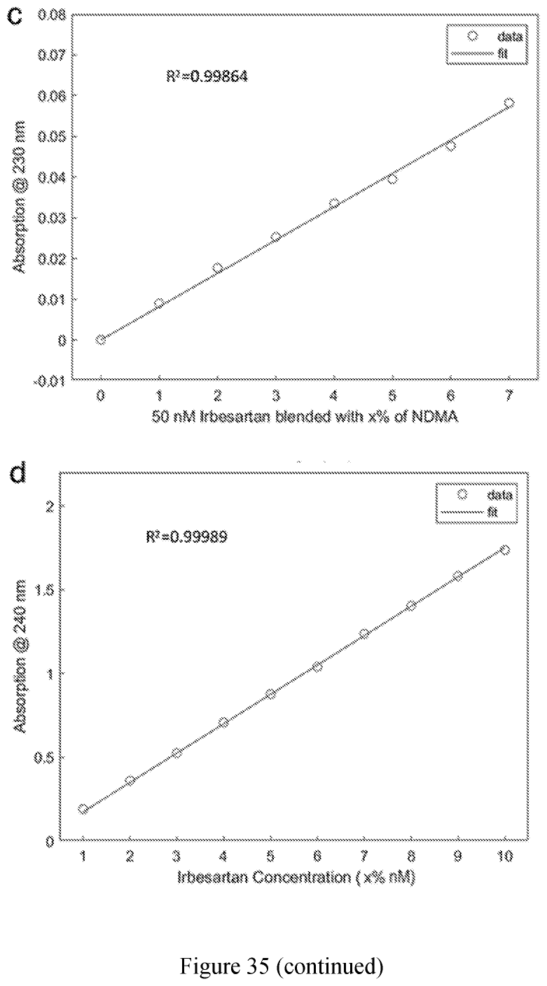

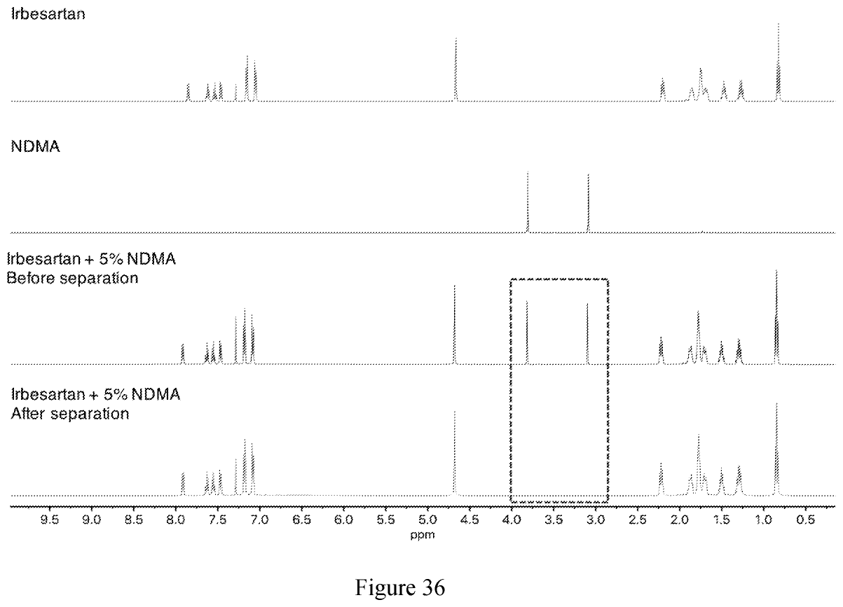

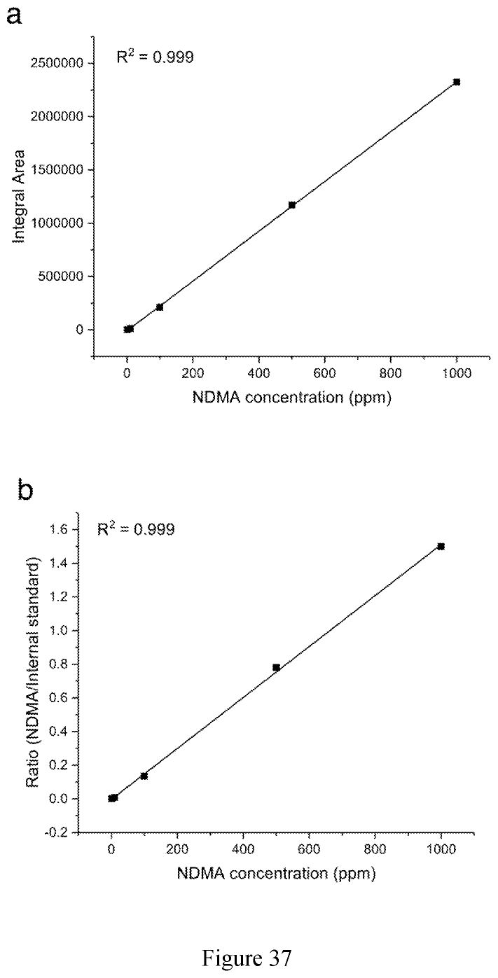

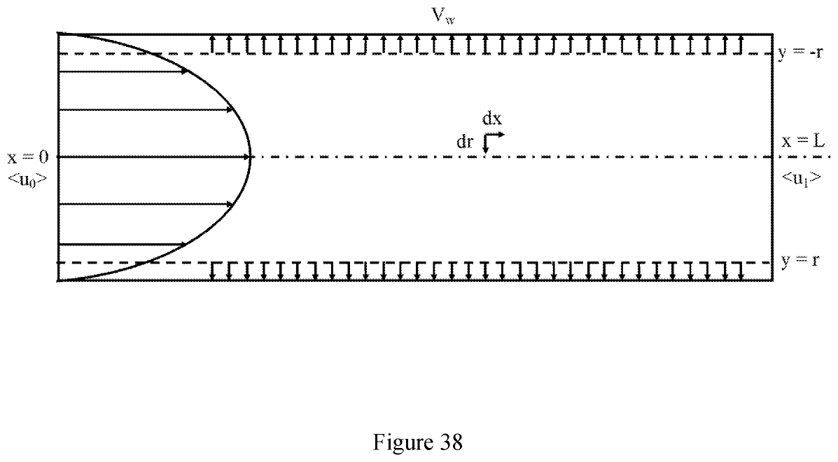

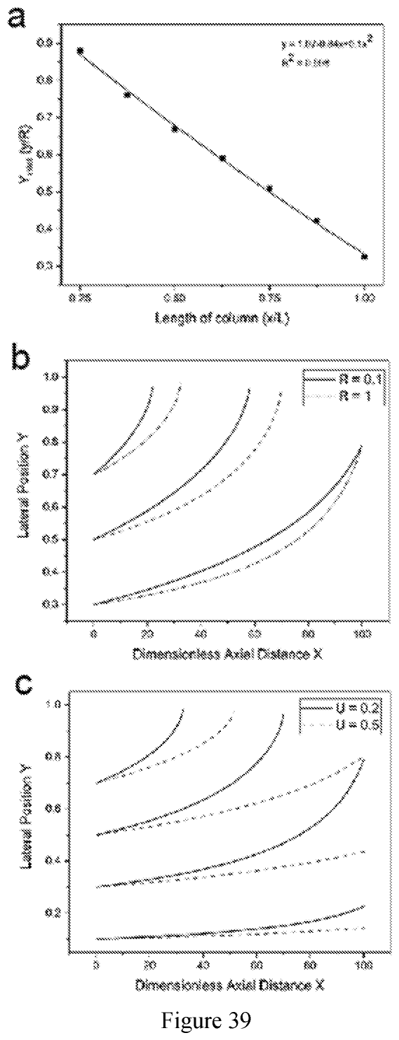

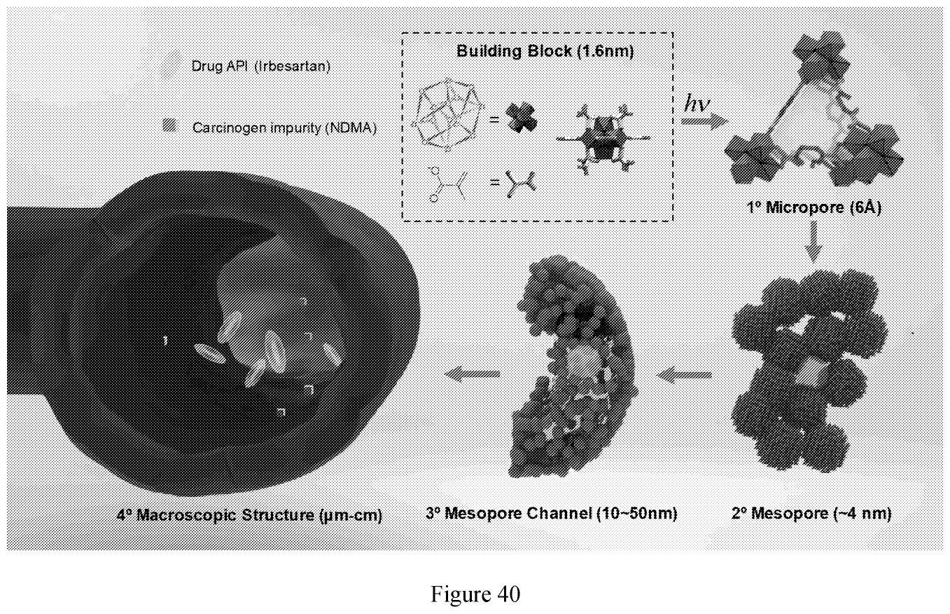

Having established the relationship between processing conditions and pore size distribution, the performance in chemical separation applications was tested. The fabrication of these meso-scale porous materials can be combined with light processing approaches to create structures in which flow channels can be defined from the μm to cm scale. Initially, printing a micro/mesoporous monolith fully in a syringe similar to a solid phase extraction setup. Separation experiments to remove MDMA showed a reduction in the carcinogen level from 5% in the inlet feed to 0% in the outlet (FIGS. 35 and 36), which validates the use of superstructures for angstrom-precise size separation. However, even given the exceptional hierarchy of large and small mesopores to help transportation, the flow rate through monolithic structures is still limited to around 1-2 ml/hour due to high backpressures, which is the critical bottleneck for almost all separation technologies.

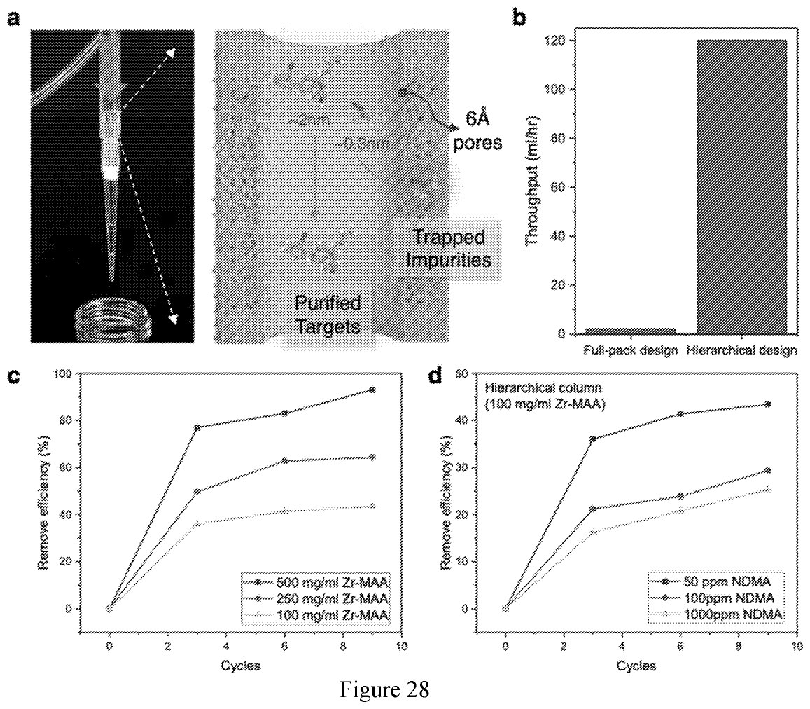

The freedom to fabricate complex shapes was leveraged using the processing method to explore different macroscopic structures to resolve the backpressure challenge. Inspired by hierarchical design present in nature, a structure similar to that of an intestine was adopted. This more efficient design increases the flow rate from ml/hours to ml/minutes. A hollow tube superstructure (akin to a hollow fiber membrane commonly used in separation processes) was fabricated with the macroscopic channel for transportation, and the wall was used liked villi to absorb impurities (FIG. 28a). FIG. 28b concludes the improvement in throughput by hierarchical design compared with the common fully-packed design. The removal efficiency of hierarchically designed superstructures prepared with different concentrations of Zr-MAA were studied in FIG. 28c. Higher concentrations of Zr-MAA precursor shows better removal efficiency. The result is consistent to the gas phase studies supporting that more micropores help the separation performance. The optimized superstructure shows 93% MDMA removal efficiency after 9 cycles, bringing the concentration down from an initial 50 ppm to less than 4 ppm, at a flow rate of 2 ml/min, which is tens of times faster than the fully-packed design.

The removal efficiency with different initial MDMA concentrations was examined (FIG. 28d) and a simplified analytical model (described below) to explain boundary layer phenomenon. The results highlight the importance and potential to achieve contradicting throughput and performance at the same time by rationally designing in macroscopic scale. To date, relatively few studies to date have taken macroscopic design into consideration because of the insufficient processing approaches available.

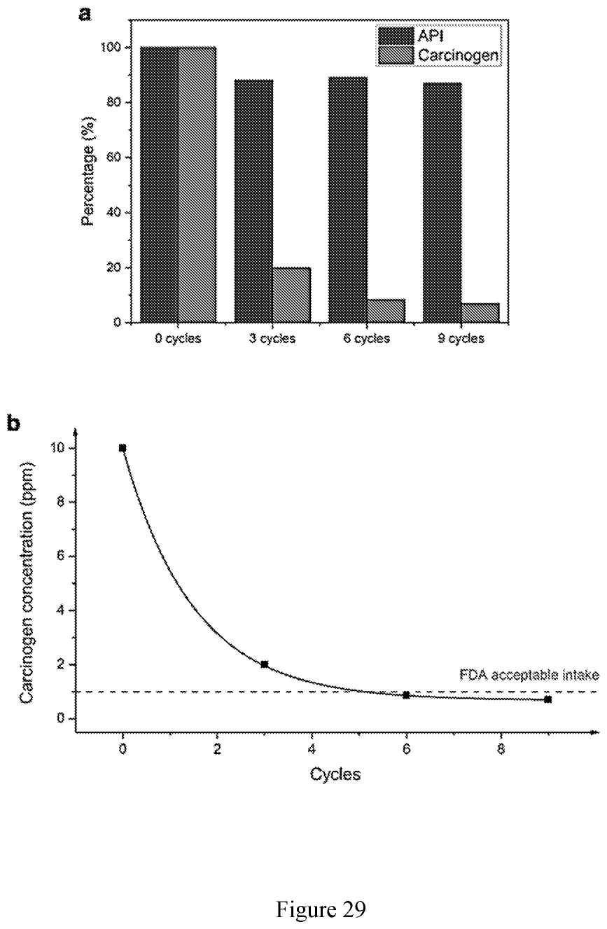

The yield and performance was tested in the separation of the MDMA from a recalled batch of pharmaceuticals as shown in FIG. 29. On average, the recalled drugs surpass the FDA approved intake amount by more than ten times the limit. Thus, experiments with a mixture containing the Irbesartan drug and 10 ppm MDMA were performed. The contaminates drop below FDA's average requirement, 1 ppm, after 6 to 9 cycles of separation shown in FIG. 29b. More importantly, the result was achieved selectively with only a ˜10% loss in the drug yield, as shown in FIG. 29a.

The hierarchical device demonstrates an opportunity of “structured” microporous materials to become an energy-efficient, cost-effective, and high-selective alternative for molecular separation processes. With the distinguishing features of solution processability in room temperature and selected low-cost precursors, the device can be fabricated on-demand within 5 minutes and for tens of dollars. In addition to its simplicity, the device is readily adaptable for potential use in various pharmaceutical scenarios, such as an additional/combined processing step of chromatography or tangential flow filtration.

Conclusion. The introduction of macroscopic design provides new experimental degrees of freedom to achieve high selectivity and throughput simultaneously. It is envisioned that diverse types of packing can be explored such as ring, saddle, and lattice to optimize area for mass transfer. Additionally, there is an unexplored space to create more complicated architectures by combining the photoresponsive ink with additive manufacturing.

The ability to assemble nanobuilding blocks to control spacing and architectures from ångström to centimeter scales by design is significant, allowing for theorists and experimentalists to access novel properties. Hierarchically porous materials shown here solve recent challenges in attaining high purity and high flow rate at the same time. Given the broad library of inorganic cores, this approach inspires a number of device architectures.

Methods. Building block synthesis. Zr-MAA was synthesized by the modified method previously reported. Briefly, 1 ml of Zr isopropoxide was mixed with 1 ml of methacrylic acid in a flask. The flask was left opened for solvent evaporation to ½ of the initial volume, and the product was washed with 1-propanol. The final product was dried under vacuum.

Fabrication of superstructures. Ink was formulated by mixing dried Zr-MAA nanoparticles from the previous step with photoinitiator and solvent. For example, 100 mg of synthesized Zr-MAA, 1 mg of photoinitiator, diphenyl(2,4,6-trimethylbenzoyl) phosphine oxide, were added into 1 ml of toluene. Inks were purged with nitrogen flow for 2 minutes before usage. Samples for gas sorption measurements were prepared by a digital light processing projector operating with 385 nm wavelength light and intensities of about 10 mW/cm². Free-standing monoliths formed as a single layer by projecting the light pattern for 2 minutes directly on top of the Si wafer. Inks with 500 mg/ml and 100 mg/ml of Zr-MAA were labelled as high and low concentration in FIG. 27.

General characterization methods. Powder X-ray diffraction characterization was carried out on Bruker-AXS D8 Discover Diffractometer using Cu K_{α} radiation at λ=1.54 Å by depositing powder onto glass substrate. The FTIR was conducted on Bruker Hyperion FT-IR Spectrometer & Microscope. A background scan was collected before each measurement (64 scans), sample scan was an average of 64 scans, and resolution was set 4 with a data spacing of 0.482 cm⁻¹. The concentration of NDMA carcinogen was measured by Shimadzu 2030 Gas Chromatography (GC) following the FDA's method. Generally, samples were held at 50° C. for 2 min, ramped from 40° to 100° C. at 5° C./min, ramped from 100° C. to 220° C. at 20° C./min, ramped from 220° C. to 250° C. at 30° C./min, and then held at 250° C. for 2 min. ¹H NMR spectra were recorded on a Bruker AV500 spectrometer with 16 scans and 45 deg excitation pulse. NMR data was analyzed by MestReNova.

Gas sorption. Samples for gas sorption were washed and exchanged with methanol for 24 hours. Then samples were dried with supercritical carbon dioxide dryer (Leica CPD300 critical point dryer). Gas adsorption measurements were carried out using a Micromeritics 3-flex gas sorption analyzer and high purity Ar or CO₂ (99.999% pure).

Liquid phase separation. Ink with different concentrations of Zr-MAA was loaded into a cylindrical plastic tube, and then exposed with UV light (385 nm, 10 mW/cm²) for 5 min. For hierarchical design devices, the ink was injected into a cylindrical plastic tube (radius 5 mm) with a needle (radius 1.5 mm) inserted in the middle (FIG. 34). Then the tube was exposed with UV light. Once the superstructure formed, the needle was removed and the device was connected to a syringe pump. To clean the superstructure, ethanol was continuously flowing through and the UV-Vis spectrum of the outlet flow was monitored. After the adsorption peak of unreacted clusters and toluene reduced to zero, a mixture of API and NDMA was flowed through the superstructure iteratively and sampled. For example, a 5 ml ethanol solution of API (2 mg/ml) and NDMA (0.01 mg/ml) was flowed iteratively through the as-prepared column at a flowrate of 2 ml/min. After the outflow is collected, it was injected back into the column for another cycle. Every cycle, 100 μL was taken from the collected outflow for quantitative GC tests.

Yield calculation. The concentration of drug was calculated with internal standard (TMS) by NMR:

$${Concentration}_{A} = \frac{{integral}_{A} / {N}_{A}}{{integral}_{T M S} / {N}_{T M S}} \times c o n c e n t r a t i o {n}_{T M S}$$

The concentration of carcinogen was calculated with internal standard (dodecane) by GC:

$${Concentration}_{B} = \frac{i n t e g r a {l}_{B}}{i n t e g r a {l}_{d o d e c a n e}} \times c o n c e n t r a t i o {n}_{d o d e c a n e}$$

The yield was calculated based on the initial concentration of each batch of runs.

Although the present disclosure has been described with respect to one or more particular examples, it will be understood that other examples of the present disclosure may be made without departing from the scope of the present disclosure.

1. A composition comprising
a plurality of reactive components, the individual reactive components comprising
an inorganic core, wherein the inorganic core is mesoporous and/or microporous, and
one or more photoreactive ligand(s),
wherein the photoreactive ligands are bound to the inorganic core by one or more chemical bond(s).

2. The composition of claim 1, wherein the inorganic core, is chosen from metal cluster compounds, metal, metal oxide, semiconductor nanoparticles, and nanoparticle complexes.

3. The composition of claim 1, wherein the photoreactive ligand(s) are chosen from acrylate ligands, alkene ligands, and combinations thereof; and optionally at least a portion of or all of the photoreactive ligands is/are functionalized.

4. (canceled)

5. The composition of claim 1, wherein the reactive components are chosen from Zr₆O₄(OH)₄(MAA)₁₂, wherein MAA is methacrylic acid or metacylate, ZnO-MAA, Cu₂(MAA)₄, wherein MAA is methacrylic acid or metacylate, SiO₂-(3-(trimethoxysilyl)propyl methacrylic acid or methacrylate), analogs thereof, derivatives thereof, and combinations thereof.

6. The composition of claim 1, wherein the composition further comprises one or more photoinitiator(s); and optionally wherein the photoinitiator(s) is/are chosen from free radical photoinitiators, cationic photoinitiators, nanoparticle based photoinitiators, photo-acid generators, and combinations thereof.

7. (canceled)

8. The composition of claim 1, wherein the composition further comprises one or more crosslinker(s).

9. The composition of claim 8, wherein the crosslinker(s) is/are chosen from multi-thiol groups, multi-acrylate groups, and combinations thereof.

10. The composition of claim 1, wherein the composition further comprises one or more oligomer(s).

11. The composition of claim 10, wherein the oligomer(s) is/are chosen from oligomers and polymers of epoxy acrylates, aliphatic urethane acrylates, aromatic urethane acrylates, ester acrylates, acrylic acrylates, and combinations thereof.

12. The composition of claim 1, wherein the composition further comprises one or more solvent(s) and optionally wherein the solvent(s) is/are chosen from aromatic solvents, aliphatic solvents, polyethers, oligoethers, halogenated organic solvents, and combinations thereof.

13. (canceled)

14. A method of forming an article of manufacture comprising:
exposing a first layer or a selected portion of a first layer of a first composition of claim 1 to electromagnetic radiation such that a plurality of the reactive components of the composition react and a first layer of a polymerized material is formed;
optionally, forming a second layer of a second composition of claim 1,
optionally, exposing the second layer or a selected portion of the second layer to electromagnetic radiation such that a plurality of the reactive components of the second composition react and a second layer of a second polymerized material is formed, and wherein the article of manufacture is formed.

15.-30. (canceled)

31. The method of claim 14, wherein the article of manufacture is porous.

32.-37. (canceled)

38. A three-dimensional (3D) article of manufacture comprising a network of crosslinked reactive components, the individual reactive components comprising an inorganic core and one or more photoreactive ligand(s), wherein the photoreactive ligands are bound to the inorganic core by one or more chemical bond(s), and wherein at least a portion or all of the article of manufacture has a microporous network, a mesoporous network, a macroporous network, or a combination thereof.

39. The 3D article of manufacture of claim 38, wherein the 3D article of manufacture is a monolithic structure, a free-standing film, or a film disposed on at least a portion of or all of a substrate.

40. (canceled)

41. The 3D article of manufacture of claim 38, the 3D article of manufacture comprises macropores, each macropore having at least one dimension of 500 microns to 1 micron and/or at least a portion of or all of the inorganic cores are microporous and/or mesoporous.

42. The 3D article of manufacture of claim 38, wherein the 3D article of manufacture has a hierarchical porosity and/or a hierarchical pore gradient.

43. (canceled)

44. The 3D article of manufacture of claim 38, wherein the 3D article of manufacture has a constant composition.

45. The 3D article of manufacture of claim 38, wherein at least a portion of or the majority of the 3D article of manufacture has a different composition from the other portion(s) of the article of manufacture.

46. (canceled)

47. The 3D article of manufacture of claim 38, wherein the 3D article of manufacture is a part of a microfluidic device, HPLC column, fluidic channel, point of care device, or diagnostics device.

48. The composition of claim 1, wherein the composition is configured to react and form a hierarchical porous structure comprising micropores, mesopores and macropores.

49. The composition of claim 1, wherein the composition has multi-scale porosities comprising micrometer scale pores, nanometer scale pores, and/or sub-nm scale pores.
